(19) United States
(12) Patent Application Publication
(10) Pub. No.: US 2021/0258019 A1
(43) Pub. Date: Aug. 19, 2021

(54) APPARATUSES, METHODS AND SYSTEMS FOR EFFICIENT AD-HOC QUERYING OF DISTRIBUTED DATA

(71) Applicant: Quantifind, Inc., Menlo Park, CA (US)

(72) Inventors: Ryan LeCompte, Milpitas, CA (US); Andrew Steele, Seattle, WA (US)

(21) Appl. No.: 17/306,678

(22) Filed: May 3, 2021

Related U.S. Application Data
(63) Continuation of application No. 14/929,246, filed on Oct. 30, 2015.
(60) Provisional application No. 62/072,923, filed on Oct. 30, 2014.

(51) Int. Cl. H03M 7/30; G06F 16/2458

(52) U.S. Cl. CPC H03M 7/30; G06F 16/2471

(57) ABSTRACT

The APPARATUSES, METHODS AND SYSTEMS FOR EFFICIENT AD-HOC QUERYING OF DISTRIBUTED DATA (“RTC”) provides a platform that, in various embodiments, is configurable to provide fast ad-hoc querying against large volumes of data. In one embodiment, the RTC is configurable to select a subset of fields from raw data in association with a domain and compact the corresponding data. Such packed records may be distributed to one or more worker nodes, which maintain the records and associated indexes. A master server facilitates query processing across the worker nodes.

### PRIORITY CLAIM

This application is a Non-Provisional of and claims priority under 35 U.S.C. § 119 to prior U.S. provisional patent application Ser. No. 62/072,926 entitled, “APPARATUSES, METHODS AND SYSTEMS FOR EFFICIENT AD-HOC QUERYING OF DISTRIBUTED DATA,” filed Oct. 30, 2014, the entirety of which is expressly incorporated herein by reference.

### FIELD

The present innovations generally address efficient distributed storage and querying of data, and more particularly, include APPARATUSES, METHODS AND SYSTEMS FOR EFFICIENT AD-HOC QUERYING OF DISTRIBUTED DATA.

### BACKGROUND

The advent of the internet and mobile device technologies have brought about a sea change in the distribution and availability of information. Ubiquitous electronic communications have resulted in large volumes of information being generated and, often, made widely available.

### BRIEF DESCRIPTION OF THE DRAWINGS

The accompanying appendices and/or drawings illustrate various non-limiting, example, innovative aspects in accordance with the present descriptions:

FIG. 1 shows an implementation of data flow for data compacting in one embodiment of RTC operation;

FIG. 2A shows an implementation of data structure for compacted data in one embodiment;

FIG. 2B shows an implementation of data flow for query processing in one embodiment of RTC operation;

FIG. 3 shows an example of logic flow for pack file generation in one embodiment of RTC operation;

FIG. 4 shows an example of logic flow for master count file generation in one embodiment of RTC operation;

FIG. 5 shows an example of logic flow for map generation and use in one embodiment of RTC operation;

FIGS. 6A-6D show examples of logic flow for query processing with compact term search phrases in one embodiments of RTC operation; and

FIG. 7 shows a block diagram illustrating embodiments of a RTC controller;

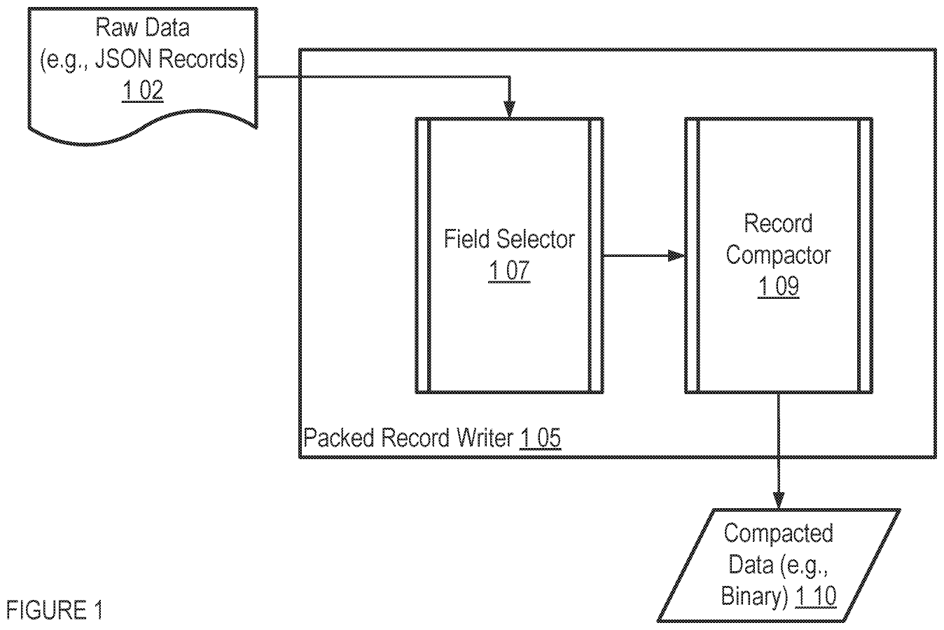

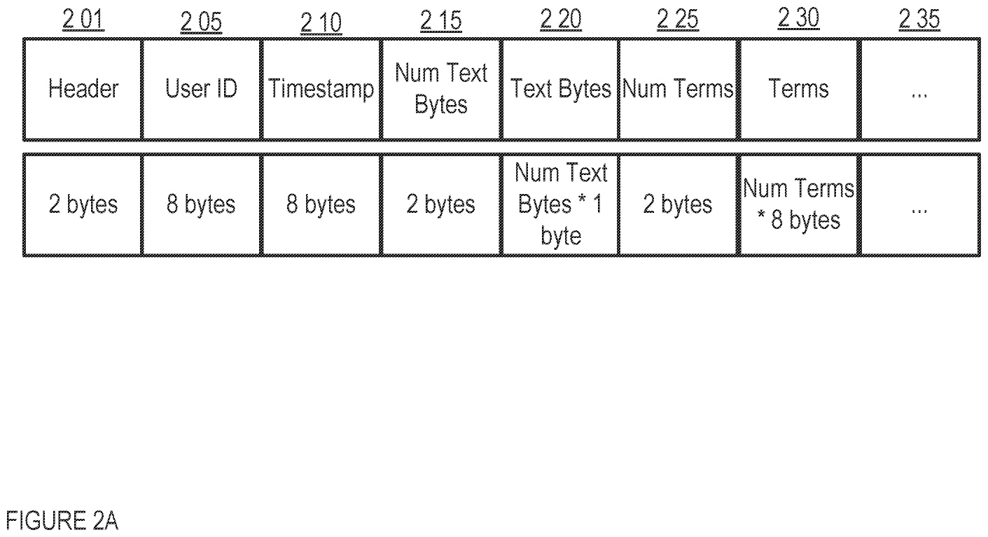

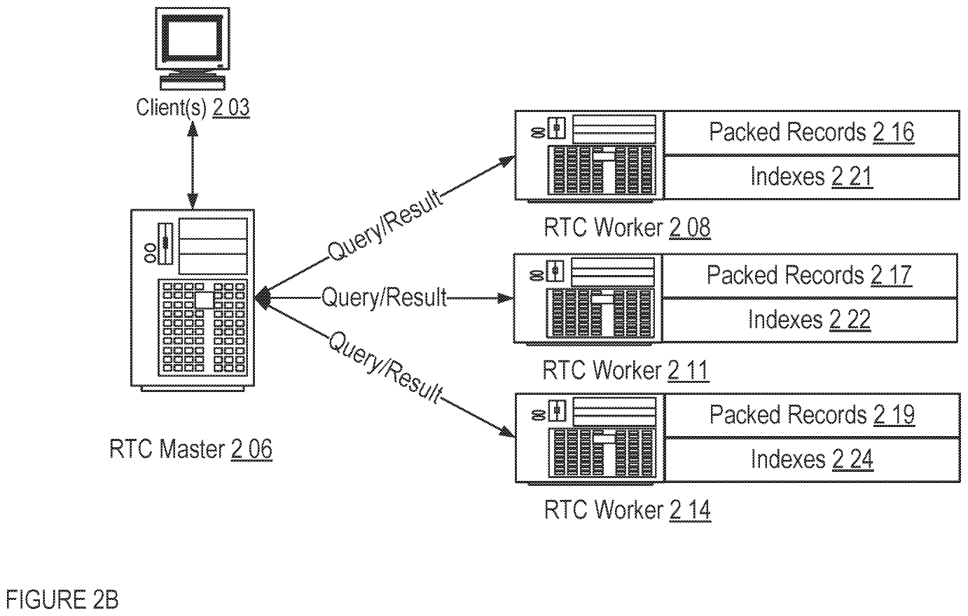

The leading number of each reference number within the drawings indicates the figure in which that reference number is introduced and/or detailed. As such, a detailed discussion of reference number 101 would be found and/or introduced in FIG. 1. Reference number 201 is introduced in FIG. 2, etc.

### DETAILED DESCRIPTION

### RTC

The APPARATUSES, METHODS AND SYSTEMS FOR EFFICIENT AD-HOC QUERYING OF DISTRIBUTED DATA (“RTC”) provides a platform that, in various embodiments, is configurable to provide fast ad-hoc querying against large volumes of data. In one embodiment, the RTC is configurable to select a subset of fields from raw data in association with a domain and compact the corresponding data. Such packed records may be distributed to one or more worker nodes, which maintain the records and associated indexes. A master server facilitates query processing across the worker nodes.

In one embodiment, RTC (Real-time Cluster) is a distributed, in-memory, real-time computing platform that supports fast ad-hoc querying against large volumes of data. RTC can be viewed, in one implementation, as an in-memory combination of map/reduce and faceted search. RTC may be used, in one implementation, for fast slicing and dicing of, for example, social data (e.g., social network post and/or feed data), terms derived therefrom, and/or the like. In one implementation, RTC apparatuses, methods and systems may include the following:
convert the data into a compact, tightly packed byte structure according to one or more customized schema/protocol (in one implementation, this reduces the size of the original JSON social joins by up to 72%);
distribute slices (e.g., by an RTC master server) of the compacted data among multiple nodes (e.g., RTC workers) in the cluster;
perform custom, on-the-fly map/reduce type operations over the compact data in-memory across all nodes;
in one implementation, execution of queries lazily unpacks only the portions of the compact records that are useful for a particular type of query
in one implementation, the system may cache “facet offsets” into the compact records to improve performance of queries that refer to a particular facet

In one implementation, a Java Virtual Machine application toolkit such as Akka Cluster may be utilized for distributed communication between the master/worker nodes in the cluster.

In one embodiment, RTC supports operations over the social data such as, but not limited to:
counts
time series
sample
top K over entities/favs
statistical “slice” compare

Querying

In one implementation, a check may be performed as to whether the cluster is up, operational, and/or the like. This may be achieved, for example, with a status call similar to the following example:

curl http://rtc:3000/status

In this example, curl is a Linux command for making HTTP requests on the command-line of a system running a Linux-based operating system. In other implementations, a user could make the HTTP request by, for example, entering a corresponding uniform resource locator (URL) into a web browser. In some embodiments, any tool that can make HTTP requests may be used as a client interface for RTC operation, including submitting queries and receiving responses.

In one implementation, the status call may also yield a list of all verticals loaded in RTC.

In one implementation, a time series over the entire vertical (e.g., counts de-duped by user/day) may be requested, such as via a command similar to the following example: curl http://rtc:3000/timeseries?targetVertical=haircare

In one implementation, appending “target” to the name of a particular field (e.g., from “Vertical” to “targetVertical”) may signify narrowing of the search query to a particular element, value, and/or the like for that field.

In one implementation, total counts over the entire vertical during a particular date and/or date range (counts de-duped by user over given time range, or over entire vertical if no time range specified) may be requested, such as via a command similar to the following example:

curl http://rtc:3000/counts?targetVertical=haircare&targetStartDate

In one implementation, a time series over the entire vertical for people talking about, for example, “hair” may be requested, such as via a command similar to the following example:

curl “http://rtc:3000/timeseries?targetVertical=haircare&targetTopic=.*hair.*”

In one implementation, a sample of haircare tweets for, e.g., Tresemme may be requested (more results may be obtained, e.g., by specifying a higher value via the sampleSize parameter), such as via a command similar to the following example:

curl “http://rtc:3000/sample?targetVertical=haircare&targetQpids=tresemme:22a42”

In one implementation, ranked entities for Tresemme tweets talking about “hair” (more results may be obtained, e.g., by specifying a higher value via the numResults parameter) may be requested, such as via a command similar to the following example:

curl “http://rtc:3000/compare?targetVertical=haircare&targetEntities=shine&targetQpids=tresemme:

In one implementation, the top 50 raw entity counts for the haircare vertical and shampoo topic (more results may be obtained, e.g., by specifying a higher value via the numResults parameter) may be requested, such as via a command similar to the following example:

curl “http://rtc:3000/entityCounts?targetVertical=haircare&targetEntities=shampoo”

In one implementation, the date entity matrix for the carrier vertical for the top K global entities K may be changed, e.g., with the numResults parameter; in one implementation, this defaults to 5000) may be requested. In one implementation, this will return a results.zip file containing the date entity matrix in MatrixMarket format.

curl “http://rtc:3000/entityCounts?targetVertical=carrier&groupBy=date”

In one implementation, the above request may be run for one or more targetQpids, such as according to the following example.

curl “http://rtc:3000/entityCounts?targetVertical=carrier&targetQpids=att:5a458&groupBy=date”

In one implementation, the top 50 raw fav counts for the haircare vertical and shampoo topic may be requested (you can get more results by specify a higher value via the numResults parameter), such as via a command similar to the following example:

curl “http://rtc:3000/favCounts?targetVertical=haircare&targetEntities=shampoo”

In one implementation, a request may be made to RTC for all qpids belonging, for example, to a particular vertical via the qpids call, e.g.:

curl “http://rtc:3000/qpids?targetVertical=carrier”

In one implementation, qpids may refer to one or more product identifiers and/or product identification codes.

Query Parameters

In one implementation, query params for the target group may include:

targetVertical=haircare
targetTopic=.*shine.*
targetQpids=tresemme:22a42
targetIntentful=true/false
targetExpr=gender:male*age:0to17|18to24*ethnicity:asian//for asian males under 25
targetStartDate=2012-05-01
targetEndDate=2012-06-01
targetState=ca-tx
targetEntities=[(shine,shiny),hair]
targetFavs=abc

Query params for the reference group:

refVertical=haircare
refTopic=.*shine.*
refQpids=tresemme:22a42
refIntentful=true/false
refExpr=gender:male*age:0to17|18to24*ethnicity:asian//for asian males under 25
refStartDate=2012-05-01
refEndDate=2012-06-01
refState=ca-tx
refEntity=bought
refEntities=[(shine,shiny),hair]
refFavs=nbc

In one implementation, the query parameters that support multiple values may include:

targetQpids/refQpids (e.g. tmobile:3160a-verizon:e77e9-sprint:05f04)
targetState/refState (e.g. ca, or ca-ga-il for all three states)
targetEntities/refEntities (e.g. (buy,buys,bought))
targetFavs/refFavs (e.g. abc or (abc,nbc,fox))

targetEntities and targetFavs Parameter Format Embodiments

Single entity example (match given entity):

targetEntities=hair

Negation example (does not match given entity, use leading “!” and surround entity in parens):

targetEntities=!(hair)

Or grouping example (matches any one, enclose in “( )”):

targetEntities=(hair, curls)

And grouping example (matches every one, enclose in “[ ]”):

targetEntities=[hair, shine]

Mix and match examples:

targetEntities=[hair,(shine,clean),!(head and shoulders)]

groupBy Parameters (in one implementation, only for entityCounts/)

In one implementation, the date entity matrix for entityCounts query in MatrixMarket format may take a form similar to the following example:

groupBy=date

numResults Parameters

In one implementation, the top K global Entities being considered for groupBy query may be limited, e.g.:

numResults=10000

Age Expression Parameter

In one implementation, the targetExpr and refExpr parameters support at least the following age buckets (leave param out entirely from URL for no age filter). Note that, in one implementation, multiple values can be specified using a pipe to separate them in order to create a bucket for the full range, e.g. for “under 25” you would specify targetExpr=age:0to17|18to24. In one implementation, must be prefaced by age: Supported age buckets may include:

0to17
8to24
5to29
0to34
5to39
0to49
0to99

Ethnicity Parameter

In one implementation, the targetExpr and refExpr parameters support at least the following values (leave param out entirely from URL for no ethnicity filter) (In one implementation, must be prefaced by ethnicity):

other
black
white
asian
hispanic

Gender Parameter

In one implementation, the targetExpr and refExpr parameters support at least the following values (leave param out entirely from URL for no gender filter)(In one implementation, must be prefaced by gender:):

male
female

US State Parameter

In one implementation, the targetState and refState parameters support at least the following values (leave param out entirely from URL for no geo/state filter)—the state abbreviation can be specified in upper or lower case as well:

AL (alabama)
AK (alaska)
AZ (arizona)
AR (arkansas)
CA (california)
CO (colorado)
CT (connecticut)
DE (delaware)
DC (district of columbia)
FL (florida)
GA (georgia)
HI (hawaii)
ID (idaho)
IL (illinois)
IN (indiana)
IA (iowa)
KS (kansas)
KY (kentucky)
LA (louisiana)
ME (maine)
MD (maryland)
MA (massachusetts)
MI (michigan)
MN (minnesota)
MS (mississippi)
MO (missouri)
MT (montana)
NE (nebraska)
NV (nevada)
NH (new hampshire)
NJ (new jersey)
NM (new mexico)
NY (new york)
NC (north carolina)
ND (north dakota)
OH (ohio)
OK (oklahoma)
OR (oregon)
PA (pennsylvania)
RI (rhode island)
SC (south carolina)
SD (south dakota)
TN (tennessee)
TX (texas)
UK (united kingdom)
UT (utah)
VT (vermont)
VA (virginia)
WA (washington)
WV (west virginia)
WI (wisconsin)
WY (wyoming)

Plotting

In one implementation, the /timeseries call supports a format=plot optional parameter that will return a zoomable chart (based on high charts) instead of a JSON time series result.

### Example

http://rtc:3000/timeseries?

targetVertical=carrier&targetQpids=att:5a458&format=plot

Multiple Target Expressions in Single Request

In one implementation, a time series or total count for multiple demos may be requested in a single call to the service. For example, multiple targetExpr params may be specified for each demo group of interest.

For example:

(JSON)

http://rtc:3000/timeseries?

targetVertical=hardwarestore&targetQpids=homedepot:7f878&targetExpr=gender:male&targetExpr=gender:female&targetExpr=(buy,buys,buying,bought)&format=json

http://rtc:3000/counts?

targetVertical=hardwarestore&targetQpids=homedepot:7f878&targetExpr=gender:male&targetExpr=genderfemale&targetExpr=(buy,buys,buying,bought)&format=json

(Plots)

http://rtc:3000/timeseries?

targetVertical=hardwarestore&targetQpids=homedepot:7f878&targetExpr=gender:male&targetExpr=genderfemale&targetExpr=(buy,buys,buying,bought)&format=plot

Request Batching

In one implementation, RTC supports at least request batching for/counts requests. Taking advantage of request batching can greatly improve the performance of a query depending on the use case. For example, in performing multiple/counts calls, one may batch them all together in a single HTTP request by taking advantage of “indexed” parameters. Each unique request may be prefixed with a unique numeric identifier prefix, e.g. [0], [1], [2], etc. Here's an example of a single batched RTC request that contains 2 indexed queries:

http://rtc:3000/counts?[0]targetVertical=restaurant& [0]targetQpids=tacobell:7d8c7&[0]targetExpr=gender:male&[0]targetEntities=(breakfast)&[1]targetVertical=restaurant&[1]targetQpids=tacobell:7d8c7&[1]targetExpr=gender:female&[1]targetEntities=(dinner)

The above request is a single HTTP request that describes two individual RTC requests. In one implementation, all parameters belonging to a particular request are indexed with the same number prefix.

In one implementation, using the RTC Scala client (see below), the request batching will be performed automatically within the client.

RTC Scala Client

In one implementation, all RTC endpoints may be accessed with a native Scala RTC client. Sample usage may take a form similar to the following example:

import com.qf.rtc._
import org.joda.time._
import com.github.nscala_time.time.Imports._
def time(f: => Unit): Long = { val start = System.currentTimeMillis; f;
System.currentTimeMillis
val client = new RTCClient(“rtc”, 3000, 3, 50)
val intentFilter = “(@dietpepsi,@pepsi)”
val topics =
Seq(
“(aspartame)”,
“(taste)”,
“(calories)”,
“(diabetes,obesity)”,
“(caffeine)”,
“(caramel)”,
“(sweet)”,
“(commercial)”,
“(flavor)”)
val topicsWithIntentFilter = topics.map { topic => s“[$intentFilter,
$topic]” } :+
val demos =
Seq(
// the “all” demo
“1.0”,
“gender:female”,
“gender:female*(0.7348*age:0to17+0.4709*age:18to24+1.9957*age:
25to29+1.9868*age:30to34+1.483*age:35t039)”
“gender:male*(0.7348*age:0to17+0.4709*age:18to24+1.9957*age:
25to29+1.9868*age:30to34+1.483*age:35to39)”
“gender:male”,
“ethnicity:white”,
“ethnicity:black”,
“ethnicity:asian”,
“ethnicity:hispanic”,
“ethnicity:other”)
val geos =
Seq(
“state:VT|CT|NY|PA|RI|NH|MA|NJ|ME”,
“state:ND|MN|IA|MI|NE|KS|MO|OH|IN|WI|IL|SD”,
“state:WA|OR|CA|AK|HI”,
“state:TN|MS|FL|DE|MD|AL|KY|GA|SC|OK|VA|AR|DC|WV|NC|TX|LA”,
“state:NV|UT|AZ|MT|CO|NM|ID|WY”)
val demoWithGeoExpressions =
for {
demo <- demos
geo <- geos
} yield s“$demo*$geo”
// monthly periods starting from Jan 1st. 20xx
val periods = Stream.iterate(RTCDates.mkDate(2012,1,1))(_ + 1.month).
takeWhile {_
time(client.call(
periods.zip(periods.tail).flatMap { case (startDt, endDt) =>
topicsWithIntentFilter.map { topic =>
TotalCountsRequest(
vertical = “beverage”,
entities = Some(topic),
qpids = Seq(“dietpepsi:cd497”),
expressions = demoWithGeoExpressions,
startDate = Some(startDt),
endDate = Some(endDt))
}
}))
client. shutdown( )

Running RTC Locally

Instructions for running the RTC locally, in one embodiment:

In one implementation, one or more .pack files may be loaded, such as according to the following:

mkdir-p $HOME/data/packedtweets
scp-r dr1:/mapr/mapr-dev/data/packed/onlinetravelservice $HOME/data/packedtweets/

In one implementation, all files are obtained (e.g., done.txt)

In some implementations, other verticals may be too big to fully load locally, e.g., on a laptop. Loading a larger vertical (e.g., carrier or beverage) may be accomplished, for example, by using a subset of the .pack files. In one implementation, any subset of .pack files may be used. In another implementation, any downloaded .pack files include at least all dictionary and user_fav_mappings files, e.g., to facilitate entity/fav-based queries.

The following are instructions for starting a master server and/or one or more worker client systems in one embodiment: In an sbt console, switch to the localPtc project, and run re-start. This will start up the master, wait (e.g., 5 seconds) for it to fully start, and then start a worker. After the worker has loaded all of the data, queries may be run against the server. The server may be stopped at any time with re-stop.

(In one implementation, when downloadeding the pack files to a different location, that location may be included as an argument to re-start, e.g. re-start—packFileDir/Users/imran/pack), e.g.:

localPtc (in build file:/Users/imran/qf/git/qfish/)
started
in the background . . .
packed.PackedTweetLocal.main( )
packed.PackedTweetLocal$: creating
INFO packed.PackedTweetLocal$: master created
INFO packed.PackedTweetLocal$: starting master . . .
INFO packed.PackedTweetLocal$: waiting for master to be up
INFO packed.PackedTweetReader$: finished reading dictionary!
INFO packed.PackedTweetLocal$: starting worker
11.669][ClusterSystem-akka.actor.default-dispatcher-3] [akka://ClusterSystem/user/master

In one implementation, a plurality of queries may be run, and then re-stop may be run to stop it (e.g., hit enter once to get an sbt prompt), e.g.:

localPtc>re-stop
[info] Stopping application localPtc (by killing the forked JVM) . . .
localPtc . . . finished with exit code 143
[success] Total time: 1 s, completed Jun. 10, 20xx 8:24:11 AM
localPtc>

Naming

In one implementation, apparatuses, methods and systems discussed herein may be referred to as a “PTC” (Packed Tweet Cluster).

FIG. 1 shows an implementation of data flow for data compacting in one embodiment of RTC operation. The input comprising one or more raw data input records 102 may, in one implementation, comprise raw text records, JSON records, and/or the like with metadata such as, but not limited to, timestamp, username, location, and/or the like (e.g., social media comment, other forms of unstructured text). The input comprising one or more raw data input records 102 may, in one implementation, be passed to downstream components (e.g., Packed Record Writer 105 comprising Field Selector 107 and Record Compactor 109) to be compacted into binary format for use in efficient search and analysis applications, subroutines, data feeds, and/or the like, In one implementation, compacting the records into a binary format as discussed herein reduces the size, e.g., by approximately 72%. In one implementation, not all fields from the original raw data are preserved; only those associated with a domain of interest. For example, in one implementation, the raw records may have certain fields selected (e.g., comment identifier, user identifier, text, timestamp, metadata, and/or the like), such as by a Field Selector module 107, which may then be passed to a record compactor module 109 for translating into a more optimized bit-packed format 110, as described in further detail herein. This bit-packed data 110 may then, in some implementations, be later read and/or consumed by other parts of the RTS and/or used as the source data when responding to incoming queries.

FIG. 2A shows an implementation of data structure for compacted data in one embodiment. A raw data record (e.g., JSON record) may be converted into a compact binary format, such as the example illustrated in FIG. 2, via a custom binary protocol which may include one or more optimizations to compact data more tightly. For example, in one implementation, the compacted representation may include a “tags” field comprising a bit vector of enabled/disabled flags, with the corresponding raw JSON record represented in a significantly more verbose manner using multiple attributes and/or fields. The illustrated implementation includes at least: a Header field (2 bytes) 201; a User ID field (8 bytes) 205; a Timestamp field (8 bytes) 210; a Num Text Bytes field (2 bytes) 215; a Text Bytes field (Num Text Bytes*1 byte) 220; a Num Terms field (2 bytes) 225; a Terms field (Num Terms*8 bytes) 230; and/or additional fields 235. In one implementation, certain fields may be configured as 64-bit SIP hashed, e.g., as an alternative to storing full text. In one implementation, fields that are one of N values may be stored in a smaller type (e.g., Byte/Short).

In another implementation, different types of packed records may be generated, maintained, accessed, analyzed, and/or the like within embodiments of RTC operation. For example, in one implementation, the RTC may include both packed comment records and packed comment records. In an implementation, a packed comment record may be constructed based on a schema and/or protocol having a form similar to the following example:

Header (2 bytes)
Sequence number (2 bytes)
Tags (2 bytes)
Timestamp (8 bytes)
User identifier (8 bytes)
Comment identifier (8 bytes)
US State (1 byte)
Number of terms (2 bytes)
Terms (number of terms*8 bytes)
Plurals bit set (based on number of terms)
Number of qpids (1 byte)
Qpids (number of qpids*2 bytes)
Number of consumer qpids (1 byte)
Consumer qpids (number of consumer qpids*2 bytes)
Number of text characters (2 bytes)
Text characters (number of UTF-8 encoded bytes)

In this example, Qpids may comprise product identification codes. In another implementation, a packed user record may be constructed based on a schema and/or protocol having a form similar to the following example:

Header (2 bytes)
Max sequence number (2 bytes)
Gender/male probability (4 bytes)
Gender/female probability (4 bytes)
Ethnicity/white probability (4 bytes)
Ethnicity/black probability (4 bytes)
Ethnicity/hispanic probability (4 bytes)
Ethnicity/asian probability (4 bytes)
Ethnicity/other probability (4 bytes)
Age/under18 probability (4 bytes)
Age/from18to20 probability (4 bytes)
Age/from21to24 probability (4 bytes)
Age/from25to29 probability (4 bytes)
Age/from30to39 probability (4 bytes)
Age/from40to49 probability (4 bytes)
Age/over50 probability (4 bytes)
Geo (1 byte)
Num favs (4 bytes)
Favs (number of favs*8 bytes)

In one implementation, Compact Terms are packed into memory according to the smallest number of bytes needed to store the compact term integer. Compact term values from 0 to 255 are stored in one byte, values from 256 to 65535 are stored in two bytes and values from 65536 to 8388607 are stored in three bytes. In one implementation, values over 8388606 are assigned the special compact term value 8388607 which is used to indicate an unmatchable term (no match term). In this way, the most common terms are represented by the smallest storage, reducing the average memory storage needs for terms.

In one implementation, text filtering may employ efficient comment queries using both single and multi-term phrases. To support single term queries, the compact terms are stored in a sorter order, allowing for binary searching. To support multi-term queries, the original term order is made available to compare adjacent terms. Therefore, the in-memory compact is composed of the following four parts:
A three byte header. In one implementation, the first byte of the header is the total number of terms in the comment text. Up to 255 terms are supported. Any terms beyond the 255th term are not included and unavailable for matching. The second byte of the header is the number of single byte (compact term values 0-255) terms. The third and final byte of the header is the number of two byte (compact term values 256-65535) terms. The number of three byte (compact term values 65536-8388607) compact terms can be determined by subtracting the sum of the single byte term count and the two byte term count from the total term count (3_byte_terms=total_terms−(1_byte_terms+2_byte_terms)).
The sorted compact terms. In one implementation, the next L bytes contains the compact terms in sorted order, where L=(1 byte*1_byte_terms)+(2 bytes*2_byte_terms)+(3 bytes*3_byte_terms). The first 1_byte_terms bytes are all of the single byte compact terms in order from the lowest to highest. The next 2*2_byte_terms bytes are the two byte compact terms in order from lowest to highest. Finally, the last 3*3_byte_terms bytes contains the three byte compact terms from lowest to highest. Terms that occur more than once in the original text are repeated as adjacent compact terms in the sorted order, one for each occurrence of the term in the original text.
The sorted to original order mapping. In one implementation, the next total_terms bytes represents the mapping between the sorted order and the original order of terms in the comment text. The value of the ith byte in this sequence of bytes will be the 0-based index of the original term position for the ith sorted compact term. The first byte will hold the original position of the first compact term in the sorted compact term section. The final byte will hold the original position of the last compact term in the sorted compact term section. Together, these bytes create a way to map from the sorted compact terms to the corresponding original positions.
The original to sorted order mapping. In one implementation, the next total_terms bytes represents the mapping between the original order of terms in the comment text and the sorted order of compact terms. The value of the ith byte in this sequence of bytes will be the 0-based index of the sorted compact term for the ith original position of the compact term. The first byte will hold the sorted position of the first compact term in the original text. The final byte will hold the sorted position of the last compact term the original text. Together, these bytes create a way to map from the original order of compact terms to the sorted order.

FIG. 2B shows an implementation of data flow for query processing in one embodiment of RTC operation. In one implementation, packed records produced via a process such as the example shown in FIG. 1 may be distributed to worker nodes for computing over a portion of those packed records. A client system 203 may, for example, submit raw data (e.g., JSON records) to an RTC master server 206 for processing and/or conversion into packed records, compacted records, .pack files, and/or the like (216, 217, 219) for storage and/or processing by one or more RTC worker systems (208, 211, 214). In one implementation, the master node keeps track of RTC workers and handles incoming queries. In one implementation, the master node orchestrates the process of assigning shards of compacted data to RTC workers. Packed records information may further be processed and/or analyzed to yield one or more indexes (221, 222, 224) to facilitate retrieval and/or provision of information in response to one or more queries, such as may be relayed by the RTC master 206, received from the client system 203, and/or the like. In one implementation, each RTC worker loads a portion of the compacted data and builds certain indexes across certain facets of the binary records. In one implementation, RTC workers (208, 211, 214) may be configured to allow building of custom facet indexes while loading .pack files, compacted records, and/or the like. For example, a tree map may be constructed, such as according to TreeMap[Long, Array[Long]], where timestamps are used as keys and values are offsets to off-heap records occurring at that time. An example of a routine for use in connection with off-heap binary searching may, in one implementation, take a form similar to the following:

```
def binarySearch{
  unsafe: Unsafe,
  offset: Long,
  fromIndex: Int,
  toIndex: Int,
  searchTerm: Long) : Int = {
  var low = fromIndex
  var high -= toIndex − 1
  var search = true
  var mid = 0
  while (search && low <= high) <
    mid = (low + high) >>> 1
    val term = unsafe.getLong (offset + (mid << 3))
    if (term < searchTerm) low − mid + 1
    else if (term > searchTerm) high = mid − 1
    else search = false
  }
  if (search) − (low + 1) else mid
}
```

Offsets may then, in one implementation, be only processed when they satisfy the applicable date range. In one implementation, raw data records may be received from a different client system from the one that later submits a query. In one implementation, the raw data records may be received and/or processed internally in the RTC master 206, may be received and/or processed at one or more RTC workers (208, 211, 214). In one implementation, a Java Virtual Machine application toolkit, such as Akka Cluster, may be utilized for distributed communication between RTC master 206 and RTC workers (208, 211, 214).

In one implementation, queries are distributed in a map/reduce approach from the RTC master to each of the RTC workers. An example of a query that queries the RTC for a time series (e.g., data points) for the first five days of 2014 against the “automobile” vertical of social media records that contain the term “fast” and the term “car” may take a form, in one embodiment, similar to the following example:

http://rtc:3000/timeseries?targetVertical=automobile&targetStartDate=2014-01-01&targetEndDate=2014-01-06&targetTerms=[fast,car]

An example of a response that this query could elicit, in one embodiment, may take a form similar to the following example:

| [ { | |
|---|---|
| “group” : 0, | |
| “groupTs”: [ { | |
| “expr”: “all”, | |
| “ts” : [ { | |
| | “date” : “2014-01-01” |
| | “count” : 137.0 |
| }, { | |
| | “date” : “2014-01-02” |
| | “count” : 188.0 |
| }, { | |
| | “date” : “2014-01-03” |
| | “count” : 212.0 |
| }, { | |
| | “date”2014-01-04” |
| | “count” : 175.0 |
| }, { | |
| “ | “date” : “2014-01-05” |
| | “count” : 168.0 |

```
    } ]
  } ]
} ]
```

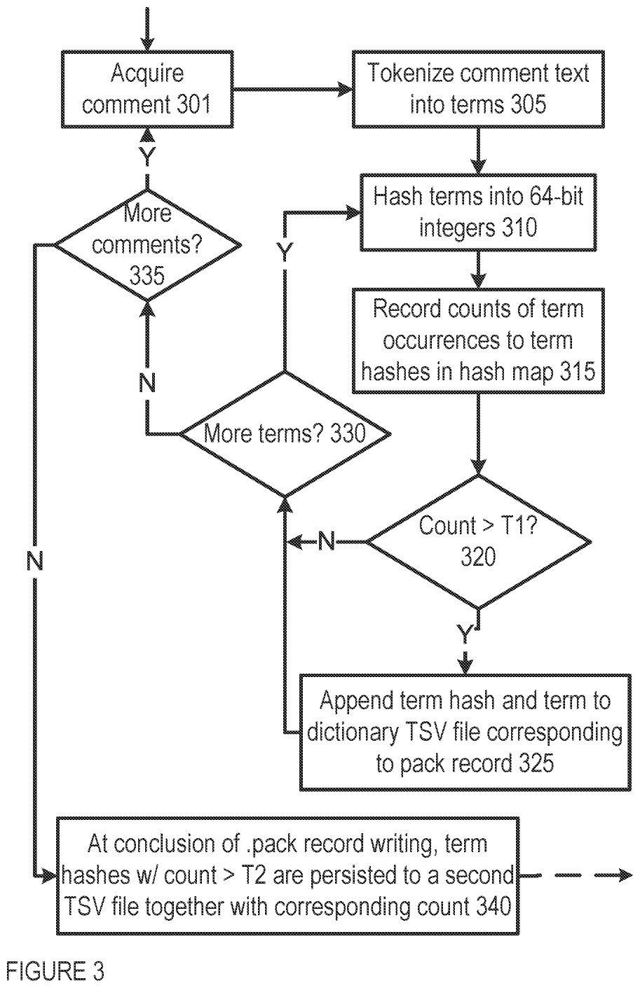

FIG. 3 shows an example of logic flow for pack file generation in one embodiment of RTC operation. During the pack file writing, the set of unique terms and the corresponding term occurrence counts are collected for all comments, e.g., in a given domain (vertical). For pack file's writing, during the processing of a comment 301, text is tokenized into terms 305. These terms are hashed, such as into 64-bit integers 310 using the SipHash 2-4 algorithm (C reference implementation here: https://131002.net/siphash/siphash24.c, incorporated in its entirety herein by reference). These hashes are stored in the comments written to the pack files. The counts of occurrences of each term are tracks by using a hash map that maps the term hash to the count value 315. This value is incremented by one for each occurrence. When the count for a term reaches a low threshold (T1, default 1) 320, the term hash and the term are appended to a dictionary TSV file corresponding to the pack file 325. At the conclusion of the of the pack file writing, when there are no more terms 330 and, in some implementations, no more comments 335, the term hashes with counts greater than or equal to the threshold value (T2) are persisted to a second TSV file (counts file) along with the corresponding count 340. In one implementation T2=T1. In another implementation, T2>T1. The count TSV may be used for remaining steps.

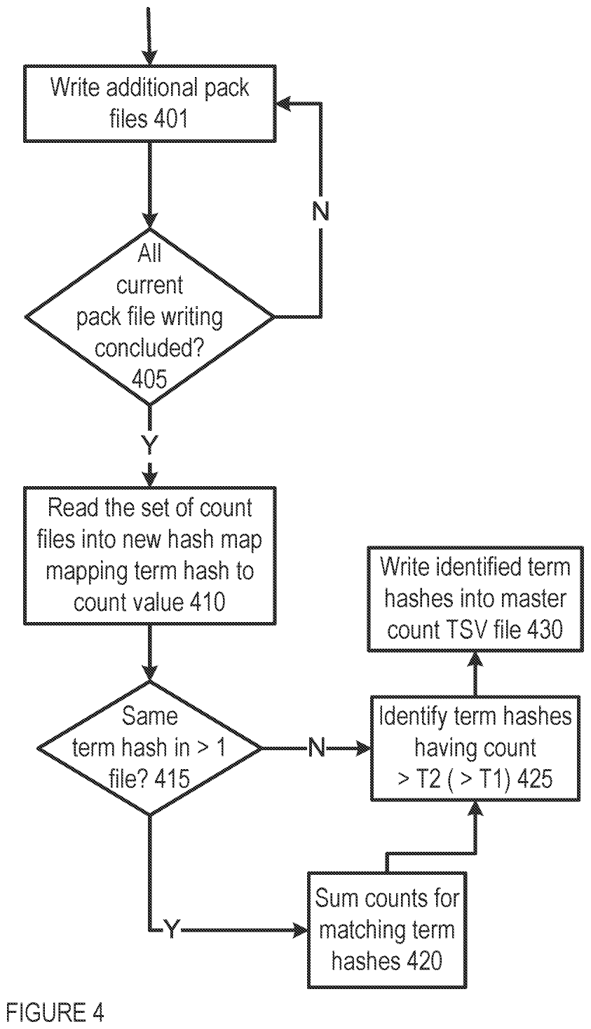

FIG. 4 shows an example of logic flow for master count file generation in one embodiment of RTC operation. In one implementation, each additional pack file may be prepared and/or collected 401, and a determination made as to whether all current pack file writing has concluded 405. At the conclusion of the writing of all pack files, the set of count files are read into a new hash map that again maps the term hash to the count value 410. When the same term hash occurs in two or more count files 415, the counts are summed 420. After all of the count files are read and accumulated, the entries whose counts are greater than or equal to a larger threshold (T2, default 50) 425 are written to a master count TSV file 430. The set of all dictionary files are combined into a single master dictionary file with duplicate entries or entries whose corresponding count is less than T2 omitted.

In one implementation, for each RTC worker loading a vertical's pack files, the term dictionary and count files may be read into memory and/or stored in two hash maps. The first hash map may, for example, map the term has to count (count map) while the second hash map may, for example, map the term hash to the term (dictionary map).

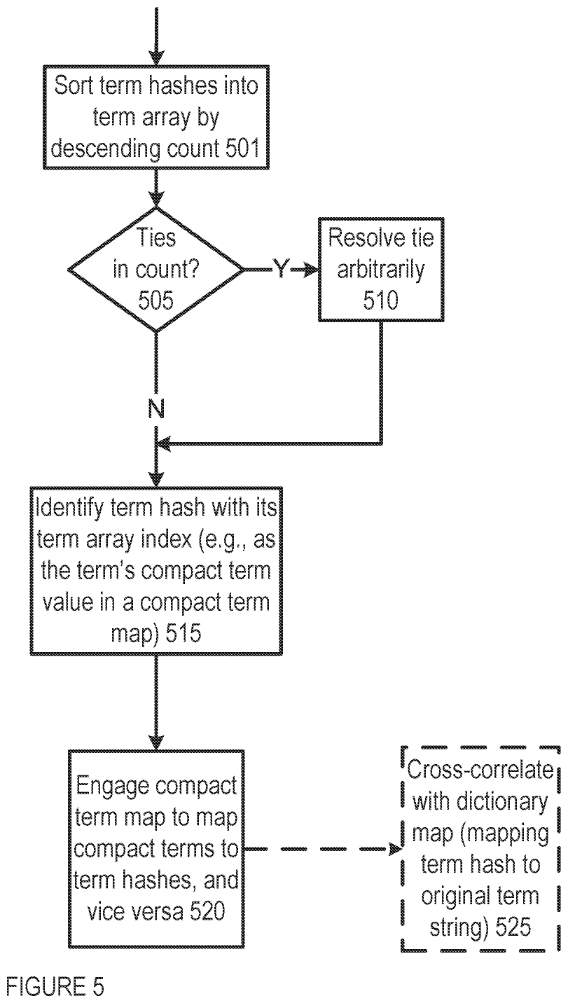

FIG. 5 shows an example of logic flow for map generation and use in one embodiment of RTC operation. In one implementation, the term hashes are sorted into an array (term array) by count descending 501, with ties identified 505 and, e.g., resolved arbitrarily 510. In another implementation, ties may be resolved based on other criteria, alphabet, chronology, and/or the like. The index of a term hash in this term array becomes the compact term value for that term 515. A map (compact term map) that maps the term hash to term array index (called compact term from now on) is created. The compact term map can be used to map a term hash into a compact term 520. The term array can be used to map a compact term back into its term hash. When combined with the dictionary map, in one implementation, the term hash can be mapped back to the original term string 525.

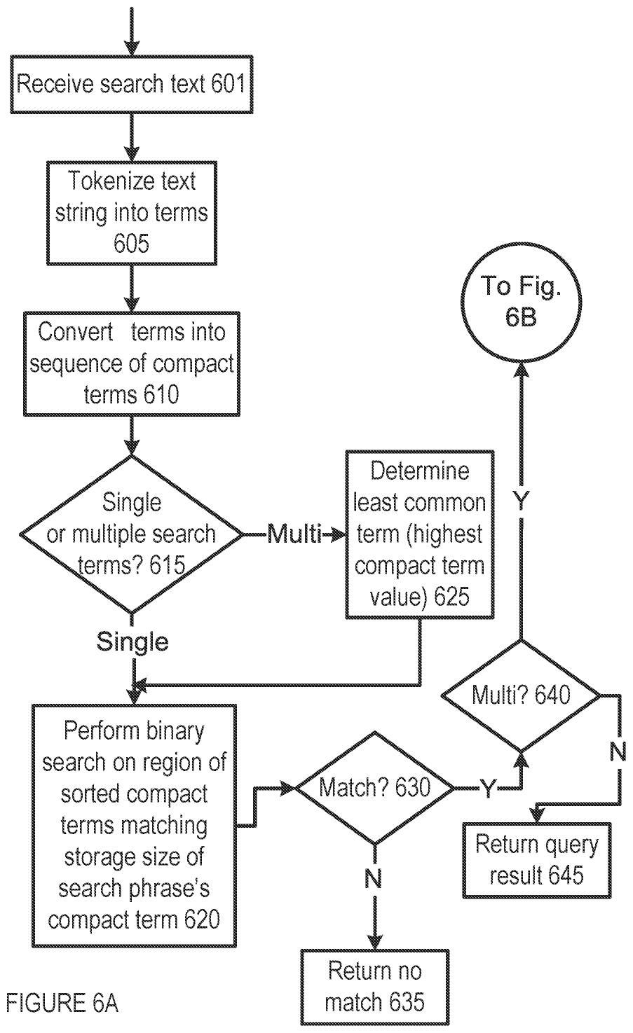

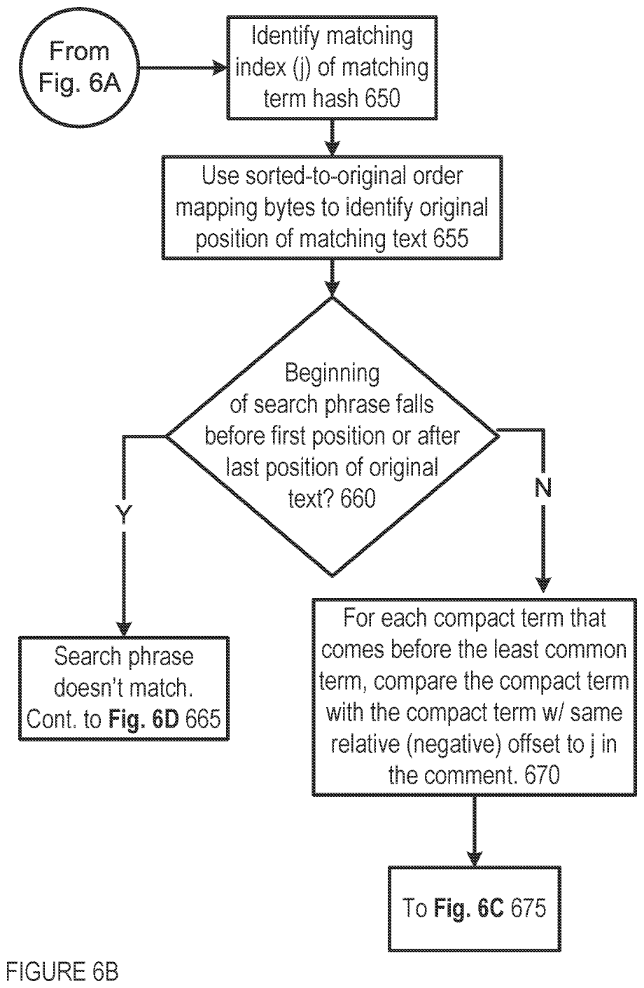

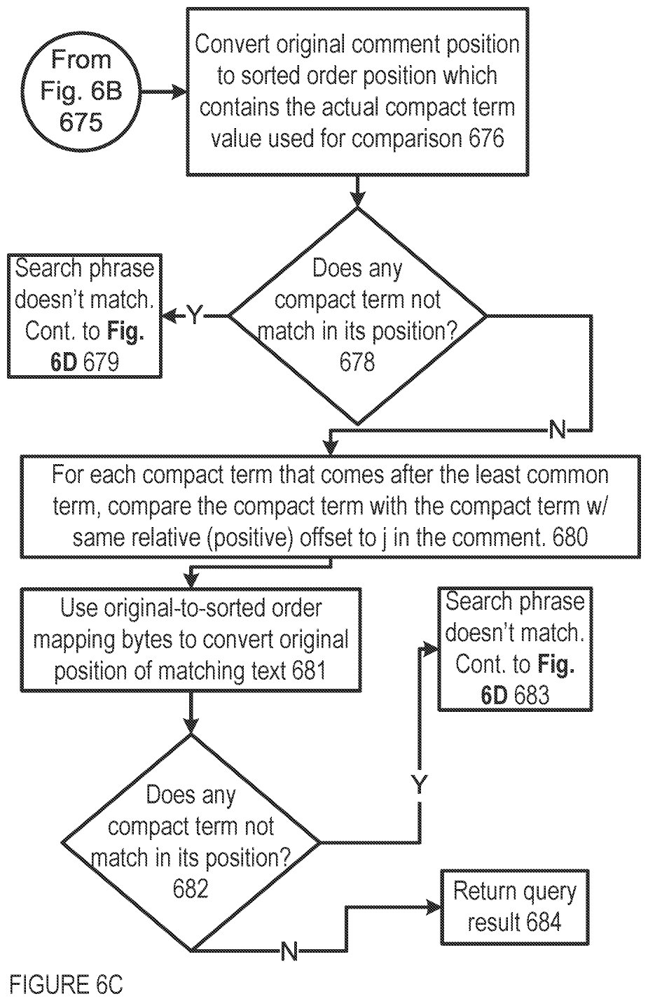

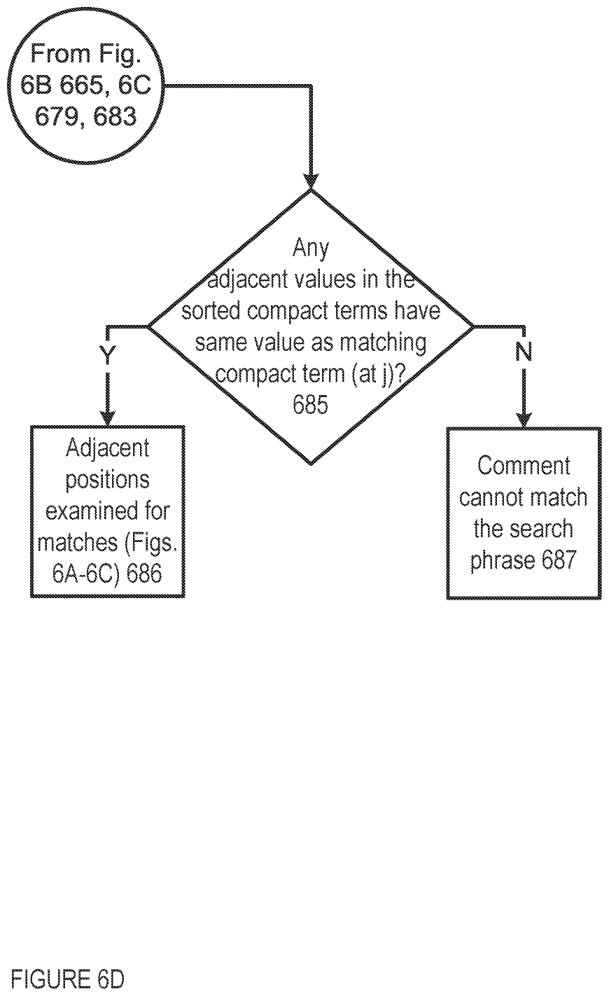

FIG. 6A shows an example of logic flow for query processing with compact term search phrases in one embodiment of RTC operation. In one implementation, compact term search phrases are used to determine if a given comment's text matches some given search text. The input search text 601 is tokenized into terms 605, e.g., using the same mechanism that was used to tokenize the comments for the given vertical being searched. The resulting terms may be converted into a sequence of compact terms 610, e.g., using the SipHash 2-4 and compact term map (from part 2). In one implementation, the matching behavior depends on the number of terms in the search phrase 615.

Single search term. When the search phrase is composed of a single term, a binary search is performed on the region of the sorted compact terms that matches the storage size of the search phrase's compact term 620. If the compact term is in the single byte range (0-255), the single byte compact terms are binary searched. If the compact term is in the two byte range (256-65535), the two byte compact terms are binary searched. If the compact term is in the three byte range (65536-8388607), the three byte compact terms are binary searched. If any match is found (and the search is not multi 640) the comment is determined to match the query 645; otherwise it does not match 635.

Multiple search terms. When the search phrase has more than one term 640, the least common term (the highest compact term value) is determined. A binary search is performed on the region of the sorted compact terms that matches the storage size of the search phrase's least common compact term in the manner described in the single search term section. If no match is found, the comment cannot match the search phrase. The least common term is used to increase the likelihood of early search failure in this step or any steps below. Otherwise If a match is found, the matching index (j) 650 is used to determine if the phrase match by examining the adjacent terms in both the phrase and the original text.

Using the sorted to original order mapping bytes, the original position of the matching index (j) may be determined 655. Based on this position, a quick determination can be made 660 to tell whether the beginning of the search phrase would fall before the first position or after the last position of the original text. In either of these cases, the search phrase cannot match in this position and the search may continue with a repeated term as described in FIG. 6D below.

Otherwise, for each compact term that comes before the least common term, the compact term is compared with the compact term with the same relative (negative) offset to j in the comment 670. The original to sorted order mapping bytes are used to convert the original comment position to the sorted order position which contains the actual compact term value used for comparison 676. The first compact term that does not match will indicate that the search phrase cannot match in this position 678 and the search may continue with a repeated term as described in FIG. 6D below 679. Otherwise if all compact terms that come before the least common term match with the corresponding compact terms in the original text, the search continues.

For each compact term that comes after the least common term, the compact term is compared with the compact term with the same relative (positive) offset to j in the comment 680. The original to sorted order mapping bytes are used to convert the original comment position 681, e.g., to the sorted order position which contains the actual compact term value used for comparison. The first compact term that does not match will indicate that the search phrase cannot match in this position 682 and the search may continue with a repeated term as described in FIG. 6D below 683. Otherwise if all compact terms that come after the least common term match with the corresponding compact terms in the original text, the match succeeds and the comment is determined to match the search phrase 684.

If this point is reached, alternative positions for matches are investigated. Positions in the sorted compact terms adjacent to j may contain other matches for the least common term in the search phrase. If any adjacent values in the sorted compact terms have the same value as the matching compact term (at position j) 685, these adjacent positions are examined for matches using the facilities discussed in FIGS. 6A-6C above 686. If there are no adjacent positions with matching compact term values or all adjacent terms with the same compact value fail to match in FIGS. 6A-6C above, the comment cannot match the search phrase 687.

In one embodiment, this design decreases the storage requirements from 2+(8*total_terms) bytes when storing the term hashes to 3+(r*total_terms) bytes when using the compact terms where r is an average between 3 and 5. Given the frequency bias towards smaller storage for the most common terms, the values of r is close to 3 in practice, typically around 3.2. This achieves an approximately 60% reduction in the bytes needed to store the terms. Further, the search performance is much faster than a linear scan when single terms used or multiple terms are used and the least common term does not match any term in the majority of comments.

### RTC Controller

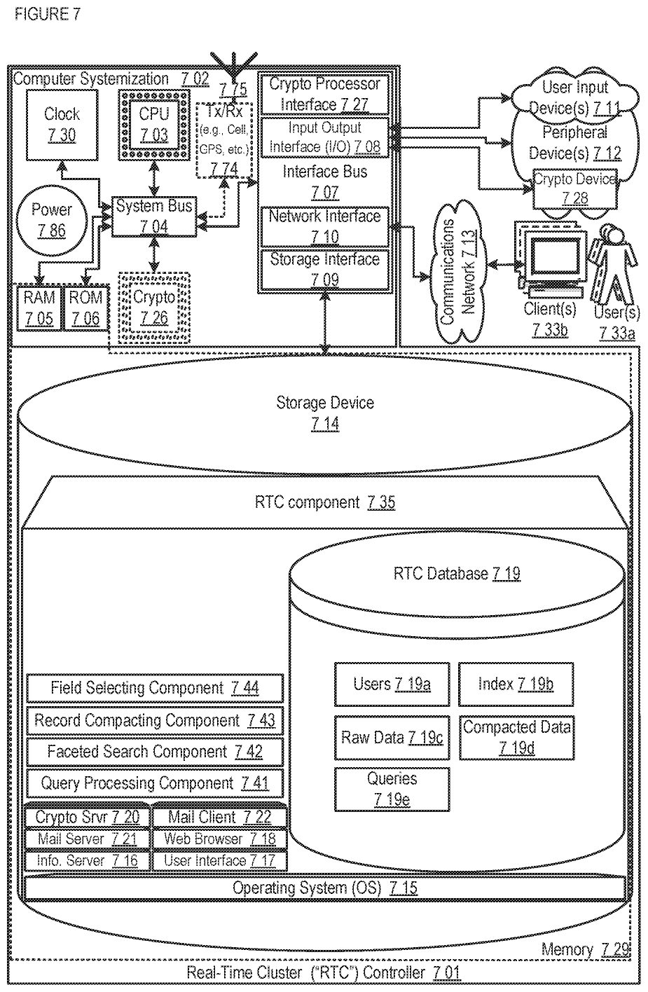

FIG. 7 shows a block diagram illustrating embodiments of a RTC controller. In this embodiment, the RTC controller 701 may serve to aggregate, process, store, search, serve, identify, instruct, generate, match, and/or facilitate interactions with a computer through market analysis technologies, and/or other related data.

Typically, users, which may be people and/or other systems, may engage information technology systems (e.g., computers) to facilitate information processing. In turn, computers employ processors to process information; such processors 703 may be referred to as central processing units (CPU). One form of processor is referred to as a microprocessor. CPUs use communicative circuits to pass binary encoded signals acting as instructions to enable various operations. These instructions may be operational and/or data instructions containing and/or referencing other instructions and data in various processor accessible and operable areas of memory 729 (e.g., registers, cache memory, random access memory, etc.). Such communicative instructions may be stored and/or transmitted in batches (e.g., batches of instructions) as programs and/or data components to facilitate desired operations. These stored instruction codes, e.g., programs, may engage the CPU circuit components and other motherboard and/or system components to perform desired operations. One type of program is a computer operating system, which, may be executed by CPU on a computer; the operating system enables and facilitates users to access and operate computer information technology and resources. Some resources that may be employed in information technology systems include: input and output mechanisms through which data may pass into and out of a computer; memory storage into which data may be saved; and processors by which information may be processed. These information technology systems may be used to collect data for later retrieval, analysis, and manipulation, which may be facilitated through a database program. These information technology systems provide interfaces that allow users to access and operate various system components.

In one embodiment, the RTC controller 701 may be connected to and/or communicate with entities such as, but not limited to: one or more users from user input devices 711; peripheral devices 712; an optional cryptographic processor device 728; and/or a communications network 713.

Networks are commonly thought to comprise the interconnection and interoperation of clients, servers, and intermediary nodes in a graph topology. It should be noted that the term “server” as used throughout this application refers generally to a computer, other device, program, or combination thereof that processes and responds to the requests of remote users across a communications network. Servers serve their information to requesting “clients.” The term “client” as used herein refers generally to a computer, program, other device, user and/or combination thereof that is capable of processing and making requests and obtaining and processing any responses from servers across a communications network. A computer, other device, program, or combination thereof that facilitates, processes information and requests, and/or furthers the passage of information from a source user to a destination user is commonly referred to as a “node.” Networks are generally thought to facilitate the transfer of information from source points to destinations. A node specifically tasked with furthering the passage of information from a source to a destination is commonly called a “router.” There are many forms of networks such as Local Area Networks (LANs), Pico networks, Wide Area Networks (WANs), Wireless Networks (WLANs), etc. For example, the Internet is generally accepted as being an interconnection of a multitude of networks whereby remote clients and servers may access and interoperate with one another.

The RTC controller 701 may be based on computer systems that may comprise, but are not limited to, components such as: a computer systemization 702 connected to memory 729.

### Computer Systemization

A computer systemization 702 may comprise a clock 730, central processing unit (“CPU(s)” and/or “processor(s)” (these terms are used interchangeable throughout the disclosure unless noted to the contrary)) 703, a memory 729 (e.g., a read only memory (ROM) 706, a random access memory (RAM) 705, etc.), and/or an interface bus 707, and most frequently, although not necessarily, are all interconnected and/or communicating through a system bus 704 on one or more (mother)board(s) 702 having conductive and/or otherwise transportive circuit pathways through which instructions (e.g., binary encoded signals) may travel to effectuate communications, operations, storage, etc. The computer systemization may be connected to a power source 786; e.g., optionally the power source may be internal. Optionally, a cryptographic processor 726 and/or transceivers (e.g., ICs) 774 may be connected to the system bus. In another embodiment, the cryptographic processor and/or transceivers may be connected as either internal and/or external peripheral devices 712 via the interface bus I/O. In turn, the transceivers may be connected to antenna(s) 775, thereby effectuating wireless transmission and reception of various communication and/or sensor protocols; for example the antenna(s) may connect to: a Texas Instruments WiLink WL1283 transceiver chip (e.g., providing 802.11n, Bluetooth 3.0, FM, global positioning system (GPS) (thereby allowing RTC controller to determine its location)); Broadcom BCM4329FKUBG transceiver chip (e.g., providing 802.11n, Bluetooth 2.1+EDR, FM, etc.); a Broadcom BCM4750IUB8 receiver chip (e.g., GPS); an Infineon Technologies X-Gold 618-PMB9800 (e.g., providing 2G/3G HSDPA/HSUPA communications); and/or the like. The system clock typically has a crystal oscillator and generates a base signal through the computer systemization's circuit pathways. The clock is typically coupled to the system bus and various clock multipliers that will increase or decrease the base operating frequency for other components interconnected in the computer systemization. The clock and various components in a computer systemization drive signals embodying information throughout the system. Such transmission and reception of instructions embodying information throughout a computer systemization may be commonly referred to as communications. These communicative instructions may further be transmitted, received, and the cause of return and/or reply communications beyond the instant computer systemization to: communications networks, input devices, other computer systemizations, peripheral devices, and/or the like. It should be understood that in alternative embodiments, any of the above components may be connected directly to one another, connected to the CPU, and/or organized in numerous variations employed as exemplified by various computer systems.

The CPU comprises at least one high-speed data processor adequate to execute program components for executing user and/or system-generated requests. Often, the processors themselves will incorporate various specialized processing units, such as, but not limited to: integrated system (bus) controllers, memory management control units, floating point units, and even specialized processing sub-units like graphics processing units, digital signal processing units, and/or the like. Additionally, processors may include internal fast access addressable memory, and be capable of mapping and addressing memory 729 beyond the processor itself; internal memory may include, but is not limited to: fast registers, various levels of cache memory (e.g., level 1, 2, 3, etc.), RAM, etc. The processor may access this memory through the use of a memory address space that is accessible via instruction address, which the processor can construct and decode allowing it to access a circuit path to a specific memory address space having a memory state. The CPU may be a microprocessor such as: AMD's Athlon, Duron and/or Opteron; ARM's application, embedded and secure processors; IBM and/or Motorola's DragonBall and PowerPC; IBM's and Sony's Cell processor; Intel's Celeron, Core (2) Duo, Itanium, Pentium, Xeon, and/or XScale; and/or the like processor(s). The CPU interacts with memory through instruction passing through conductive and/or transportive conduits (e.g., (printed) electronic and/or optic circuits) to execute stored instructions (i.e., program code) according to conventional data processing techniques. Such instruction passing facilitates communication within the RTC controller and beyond through various interfaces. Should processing requirements dictate a greater amount speed and/or capacity, distributed processors (e.g., Distributed RTC), mainframe, multi-core, parallel, and/or super-computer architectures may similarly be employed. Alternatively, should deployment requirements dictate greater portability, smaller Personal Digital Assistants (PDAs) may be employed.

Depending on the particular implementation, features of the RTC may be achieved by implementing a microcontroller such as CAST's R8051XC2 microcontroller; Intel's MCS 51 (i.e., 8051 microcontroller); and/or the like. Also, to implement certain features of the RTC, some feature implementations may rely on embedded components, such as: Application-Specific Integrated Circuit (“ASIC”), Digital Signal Processing (“DSP”), Field Programmable Gate Array (“FPGA”), and/or the like embedded technology. For example, any of the RTC component collection (distributed or otherwise) and/or features may be implemented via the microprocessor and/or via embedded components; e.g., via ASIC, coprocessor, DSP, FPGA, and/or the like. Alternately, some implementations of the RTC may be implemented with embedded components that are configured and used to achieve a variety of features or signal processing.

Depending on the particular implementation, the embedded components may include software solutions, hardware solutions, and/or some combination of both hardware/software solutions. For example, RTC features discussed herein may be achieved through implementing FPGAs, which are a semiconductor devices containing programmable logic components called “logic blocks,” and programmable interconnects, such as the high performance FPGA Virtex series and/or the low cost Spartan series manufactured by Xilinx. Logic blocks and interconnects can be programmed by the customer or designer, after the FPGA is manufactured, to implement any of the RTC features. A hierarchy of programmable interconnects allow logic blocks to be interconnected as needed by the RTC system designer/administrator, somewhat like a one-chip programmable breadboard. An FPGA's logic blocks can be programmed to perform the operation of basic logic gates such as AND, and XOR, or more complex combinational operators such as decoders or mathematical operations. In most FPGAs, the logic blocks also include memory elements, which may be circuit flip-flops or more complete blocks of memory. In some circumstances, the RTC may be developed on regular FPGAs and then migrated into a fixed version that more resembles ASIC implementations. Alternate or coordinating implementations may migrate RTC controller features to a final ASIC instead of or in addition to FPGAs. Depending on the implementation all of the aforementioned embedded components and microprocessors may be considered the “CPU” and/or “processor” for the RTC.

### Power Source

The power source 786 may be of any standard form for powering small electronic circuit board devices such as the following power cells: alkaline, lithium hydride, lithium ion, lithium polymer, nickel cadmium, solar cells, and/or the like. Other types of AC or DC power sources may be used as well. In the case of solar cells, in one embodiment, the case provides an aperture through which the solar cell may capture photonic energy. The power cell 786 is connected to at least one of the interconnected subsequent components of the RTC thereby providing an electric current to all subsequent components. In one example, the power source 786 is connected to the system bus component 704. In an alternative embodiment, an outside power source 786 is provided through a connection across the I/O 708 interface. For example, a USB and/or IEEE 1394 connection carries both data and power across the connection and is therefore a suitable source of power.

### Interface Adapters

Interface bus(ses) 707 may accept, connect, and/or communicate to a number of interface adapters, conventionally although not necessarily in the form of adapter cards, such as but not limited to: input output interfaces (I/O) 708, storage interfaces 709, network interfaces 710, and/or the like. Optionally, cryptographic processor interfaces 727 similarly may be connected to the interface bus. The interface bus provides for the communications of interface adapters with one another as well as with other components of the computer systemization. Interface adapters are adapted for a compatible interface bus. Interface adapters conventionally connect to the interface bus via a slot architecture. Conventional slot architectures may be employed, such as, but not limited to: Accelerated Graphics Port (AGP), Card Bus, (Extended) Industry Standard Architecture ((E)ISA), Micro Channel Architecture (MCA), NuBus, Peripheral Component Interconnect (Extended) (PCI(X)), PCI Express, Personal Computer Memory Card International Association (PCMCIA), and/or the like.

Storage interfaces 709 may accept, communicate, and/or connect to a number of storage devices such as, but not limited to: storage devices 714, removable disc devices, and/or the like. Storage interfaces may employ connection protocols such as, but not limited to: (Ultra) (Serial) Advanced Technology Attachment (Packet Interface) ((Ultra) (Serial) ATA(PI)), (Enhanced) Integrated Drive Electronics ((E)IDE), Institute of Electrical and Electronics Engineers (IEEE) 1394, fiber channel, Small Computer Systems Interface (SCSI), Universal Serial Bus (USB), and/or the like.

Network interfaces 710 may accept, communicate, and/or connect to a communications network 713. Through a communications network 713, the RTC controller is accessible through remote clients 733b (e.g., computers with web browsers) by users 733a. Network interfaces may employ connection protocols such as, but not limited to: direct connect, Ethernet (thick, thin, twisted pair 10/100/1000 Base T, and/or the like), Token Ring, wireless connection such as IEEE 802.11a-x, and/or the like. Should processing requirements dictate a greater amount speed and/or capacity, distributed network controllers (e.g., Distributed RTC), architectures may similarly be employed to pool, load balance, and/or otherwise increase the communicative bandwidth required by the RTC controller. A communications network may be any one and/or the combination of the following: a direct interconnection; the Internet; a Local Area Network (LAN); a Metropolitan Area Network (MAN); an Operating Missions as Nodes on the Internet (OMNI); a secured custom connection; a Wide Area Network (WAN); a wireless network (e.g., employing protocols such as, but not limited to a Wireless Application Protocol (WAP), I-mode, and/or the like); and/or the like. A network interface may be regarded as a specialized form of an input output interface. Further, multiple network interfaces 710 may be used to engage with various communications network types 713. For example, multiple network interfaces may be employed to allow for the communication over broadcast, multicast, and/or unicast networks.

Input Output interfaces (I/O) 708 may accept, communicate, and/or connect to user input devices 711, peripheral devices 712, cryptographic processor devices 728, and/or the like. I/O may employ connection protocols such as, but not limited to: audio: analog, digital, monaural, RCA, stereo, and/or the like; data: Apple Desktop Bus (ADB), IEEE 1394a-b, serial, universal serial bus (USB); infrared; joystick; keyboard; midi; optical; PC AT; PS/2; parallel; radio; video interface: Apple Desktop Connector (ADC), BNC, coaxial, component, composite, digital, Digital Visual Interface (DVI), high-definition multimedia interface (HDMI), RCA, RF antennae, S-Video, VGA, and/or the like; wireless transceivers: 802.11a/b/g/n/x; Bluetooth; cellular (e.g., code division multiple access (CDMA), high speed packet access (HSPA(+)), high-speed downlink packet access (HSDPA), global system for mobile communications (GSM), long term evolution (LTE), WiMax, etc.); and/or the like. One typical output device may include a video display, which typically comprises a Cathode Ray Tube (CRT) or Liquid Crystal Display (LCD) based monitor with an interface (e.g., DVI circuitry and cable) that accepts signals from a video interface, may be used. The video interface composites information generated by a computer systemization and generates video signals based on the composited information in a video memory frame. Another output device is a television set, which accepts signals from a video interface. Typically, the video interface provides the composited video information through a video connection interface that accepts a video display interface (e.g., an RCA composite video connector accepting an RCA composite video cable; a DVI connector accepting a DVI display cable, etc.).

User input devices 711 often are a type of peripheral device 512 (see below) and may include: card readers, dongles, finger print readers, gloves, graphics tablets, joysticks, keyboards, microphones, mouse (mice), remote controls, retina readers, touch screens (e.g., capacitive, resistive, etc.), trackballs, trackpads, sensors (e.g., accelerometers, ambient light, GPS, gyroscopes, proximity, etc.), styluses, and/or the like.

Peripheral devices 712 may be connected and/or communicate to I/O and/or other facilities of the like such as network interfaces, storage interfaces, directly to the interface bus, system bus, the CPU, and/or the like. Peripheral devices may be external, internal and/or part of the RTC controller. Peripheral devices may include: antenna, audio devices (e.g., line-in, line-out, microphone input, speakers, etc.), cameras (e.g., still, video, webcam, etc.), dongles (e.g., for copy protection, ensuring secure transactions with a digital signature, and/or the like), external processors (for added capabilities; e.g., crypto devices 528), force-feedback devices (e.g., vibrating motors), network interfaces, printers, scanners, storage devices, transceivers (e.g., cellular, GPS, etc.), video devices (e.g., goggles, monitors, etc.), video sources, visors, and/or the like. Peripheral devices often include types of input devices (e.g., cameras).

It should be noted that although user input devices and peripheral devices may be employed, the RTC controller may be embodied as an embedded, dedicated, and/or monitor-less (i.e., headless) device, wherein access would be provided over a network interface connection.

Cryptographic units such as, but not limited to, microcontrollers, processors 726, interfaces 727, and/or devices 728 may be attached, and/or communicate with the RTC controller. A MC68HC16 microcontroller, manufactured by Motorola Inc., may be used for and/or within cryptographic units. The MC68HC16 microcontroller utilizes a 16-bit multiply-and-accumulate instruction in the 16 MHz configuration and requires less than one second to perform a 512-bit RSA private key operation. Cryptographic units support the authentication of communications from interacting agents, as well as allowing for anonymous transactions. Cryptographic units may also be configured as part of the CPU. Equivalent microcontrollers and/or processors may also be used. Other commercially available specialized cryptographic processors include: Broadcom's CryptoNetX and other Security Processors; nCipher's nShield; SafeNet's Luna PCI (e.g., 7100) series; Semaphore Communications' 40 MHz Roadrunner 184; Sun's Cryptographic Accelerators (e.g., Accelerator 6000 PCIe Board, Accelerator 500 Daughtercard); Via Nano Processor (e.g., L2100, L2200, U2400) line, which is capable of performing 500+MB/s of cryptographic instructions; VLSI Technology's 33 MHz 6868; and/or the like.

### Memory

Generally, any mechanization and/or embodiment allowing a processor to affect the storage and/or retrieval of information is regarded as memory 729. However, memory is a fungible technology and resource, thus, any number of memory embodiments may be employed in lieu of or in concert with one another. It is to be understood that the RTC controller and/or a computer systemization may employ various forms of memory 729. For example, a computer systemization may be configured wherein the operation of on-chip CPU memory (e.g., registers), RAM, ROM, and any other storage devices are provided by a paper punch tape or paper punch card mechanism; however, such an embodiment would result in an extremely slow rate of operation. In a typical configuration, memory 729 will include ROM 706, RAM 705, and a storage device 714. A storage device 714 may be any conventional computer system storage. Storage devices may include a drum; a (fixed and/or removable) magnetic disk drive; a magneto-optical drive; an optical drive (i.e., Blueray, CD ROM/RAM/Recordable (R)/ReWritable (RW), DVD R/RW, HD DVD R/RW etc.); an array of devices (e.g., Redundant Array of Independent Disks (RAID)); solid state memory devices (USB memory, solid state drives (SSD), etc.); other processor-readable storage mediums; and/or other devices of the like. Thus, a computer systemization generally requires and makes use of memory.

### Component Collection

The memory 729 may contain a collection of program and/or database components and/or data such as, but not limited to: operating system component(s) 715 (operating system); information server component(s) 716 (information server); user interface component(s) 717 (user interface); Web browser component(s) 718 (Web browser); database(s) 719; mail server component(s) 721; mail client component(s) 722; cryptographic server component(s) 720 (cryptographic server); the RTC component(s) 735; and/or the like (i.e., collectively a component collection). These components may be stored and accessed from the storage devices and/or from storage devices accessible through an interface bus. Although non-conventional program components such as those in the component collection, typically, are stored in a local storage device 714, they may also be loaded and/or stored in memory such as: peripheral devices, RAM, remote storage facilities through a communications network, ROM, various forms of memory, and/or the like.

### Operating System

The operating system component 715 is an executable program component facilitating the operation of the RTC controller. Typically, the operating system facilitates access of I/O, network interfaces, peripheral devices, storage devices, and/or the like. The operating system may be a highly fault tolerant, scalable, and secure system such as: Apple Macintosh OS X (Server); AT&T Plan 9; Be OS; Unix and Unix-like system distributions (such as AT&T's UNIX; Berkley Software Distribution (BSD) variations such as FreeBSD, NetBSD, OpenBSD, and/or the like; Linux distributions such as Red Hat, Ubuntu, and/or the like); and/or the like operating systems. However, more limited and/or less secure operating systems also may be employed such as Apple Macintosh OS, IBM OS/2, Microsoft DOS, Microsoft Windows 2000/2003/3.1/95/98/CE/Millenium/NT/Vista/XP (Server), Palm OS, and/or the like. An operating system may communicate to and/or with other components in a component collection, including itself, and/or the like. Most frequently, the operating system communicates with other program components, user interfaces, and/or the like. For example, the operating system may contain, communicate, generate, obtain, and/or provide program component, system, user, and/or data communications, requests, and/or responses. The operating system, once executed by the CPU, may enable the interaction with communications networks, data, I/O, peripheral devices, program components, memory, user input devices, and/or the like. The operating system may provide communications protocols that allow the RTC controller to communicate with other entities through a communications network 713. Various communication protocols may be used by the RTC controller as a subcarrier transport mechanism for interaction, such as, but not limited to: multicast, TCP/IP, UDP, unicast, and/or the like.

### Information Server

An information server component 716 is a stored program component that is executed by a CPU. The information server may be a conventional Internet information server such as, but not limited to Apache Software Foundation's Apache, Microsoft's Internet Information Server, and/or the like. The information server may allow for the execution of program components through facilities such as Active Server Page (ASP), ActiveX, (ANSI) (Objective-) C (++), C # and/or .NET, Common Gateway Interface (CGI) scripts, dynamic (D) hypertext markup language (HTML), FLASH, Java, JavaScript, Practical Extraction Report Language (PERL), Hypertext Pre-Processor (PHP), pipes, Python, wireless application protocol (WAP), WebObjects, and/or the like. The information server may support secure communications protocols such as, but not limited to, File Transfer Protocol (FTP); HyperText Transfer Protocol (HTTP); Secure Hypertext Transfer Protocol (HTTPS), Secure Socket Layer (SSL), messaging protocols (e.g., America Online (AOL) Instant Messenger (AIM), Application Exchange (APEX), ICQ, Internet Relay Chat (IRC), Microsoft Network (MSN) Messenger Service, Presence and Instant Messaging Protocol (PRIM), Internet Engineering Task Force's (IETF's) Session Initiation Protocol (SIP), SIP for Instant Messaging and Presence Leveraging Extensions (SIMPLE), open XML-based Extensible Messaging and Presence Protocol (XMPP) (i.e., Jabber or Open Mobile Alliance's (OMA's) Instant Messaging and Presence Service (IMPS)), Yahoo! Instant Messenger Service, and/or the like. The information server provides results in the form of Web pages to Web browsers, and allows for the manipulated generation of the Web pages through interaction with other program components. After a Domain Name System (DNS) resolution portion of an HTTP request is resolved to a particular information server, the information server resolves requests for information at specified locations on the RTC controller based on the remainder of the HTTP request. For example, a request such as http://123.124.125.126/myInformation.html might have the IP portion of the request “123.124.125.126” resolved by a DNS server to an information server at that IP address; that information server might in turn further parse the http request for the “/myInformation.html” portion of the request and resolve it to a location in memory containing the information “myInformation.html.” Additionally, other information serving protocols may be employed across various ports, e.g., FTP communications across port 21, and/or the like. An information server may communicate to and/or with other components in a component collection, including itself, and/or facilities of the like. Most frequently, the information server communicates with the RTC database 719, operating systems, other program components, user interfaces, Web browsers, and/or the like.

Access to the RTC database may be achieved through a number of database bridge mechanisms such as through scripting languages as enumerated below (e.g., CGI) and through inter-application communication channels as enumerated below (e.g., CORBA, WebObjects, etc.). Any data requests through a Web browser are parsed through the bridge mechanism into appropriate grammars as required by the RTC. In one embodiment, the information server would provide a Web form accessible by a Web browser. Entries made into supplied fields in the Web form are tagged as having been entered into the particular fields, and parsed as such. The entered terms are then passed along with the field tags, which act to instruct the parser to generate queries directed to appropriate tables and/or fields. In one embodiment, the parser may generate queries in standard SQL by instantiating a search string with the proper join/select commands based on the tagged text entries, wherein the resulting command is provided over the bridge mechanism to the RTC as a query. Upon generating query results from the query, the results are passed over the bridge mechanism, and may be parsed for formatting and generation of a new results Web page by the bridge mechanism. Such a new results Web page is then provided to the information server, which may supply it to the requesting Web browser.

Also, an information server may contain, communicate, generate, obtain, and/or provide program component, system, user, and/or data communications, requests, and/or responses.

### User Interface

Computer interfaces in some respects are similar to automobile operation interfaces. Automobile operation interface elements such as steering wheels, gearshifts, and speedometers facilitate the access, operation, and display of automobile resources, and status. Computer interaction interface elements such as check boxes, cursors, menus, scrollers, and windows (collectively and commonly referred to as widgets) similarly facilitate the access, capabilities, operation, and display of data and computer hardware and operating system resources, and status. Operation interfaces are commonly called user interfaces. Graphical user interfaces (GUIs) such as the Apple Macintosh Operating System's Aqua, IBM's OS/2, Microsoft's Windows 2000/2003/3.1/95/98/CE/Millenium/NT/XP/Vista/7 (i.e., Aero), Unix's X-Windows (e.g., which may include additional Unix graphic interface libraries and layers such as K Desktop Environment (KDE), mythTV and GNU Network Object Model Environment (GNOME)), web interface libraries (e.g., ActiveX, AJAX, (D)HTML, FLASH, Java, JavaScript, etc. interface libraries such as, but not limited to, Dojo, jQuery(UI), MooTools, Prototype, script.aculo.us, SWFObject, Yahoo! User Interface, any of which may be used and) provide a baseline and means of accessing and displaying information graphically to users.

A user interface component 717 is a stored program component that is executed by a CPU. The user interface may be a conventional graphic user interface as provided by, with, and/or atop operating systems and/or operating environments such as already discussed. The user interface may allow for the display, execution, interaction, manipulation, and/or operation of program components and/or system facilities through textual and/or graphical facilities. The user interface provides a facility through which users may affect, interact, and/or operate a computer system. A user interface may communicate to and/or with other components in a component collection, including itself, and/or facilities of the like. Most frequently, the user interface communicates with operating systems, other program components, and/or the like. The user interface may contain, communicate, generate, obtain, and/or provide program component, system, user, and/or data communications, requests, and/or responses.

### Web Browser

A Web browser component 718 is a stored program component that is executed by a CPU. The Web browser may be a conventional hypertext viewing application such as Microsoft Internet Explorer or Netscape Navigator. Secure Web browsing may be supplied with 128 bit (or greater) encryption by way of HTTPS, SSL, and/or the like. Web browsers allowing for the execution of program components through facilities such as ActiveX, AJAX, (D)HTML, FLASH, Java, JavaScript, web browser plug-in APIs (e.g., FireFox, Safari Plug-in, and/or the like APIs), and/or the like. Web browsers and like information access tools may be integrated into PDAs, cellular telephones, and/or other mobile devices. A Web browser may communicate to and/or with other components in a component collection, including itself, and/or facilities of the like. Most frequently, the Web browser communicates with information servers, operating systems, integrated program components (e.g., plug-ins), and/or the like; e.g., it may contain, communicate, generate, obtain, and/or provide program component, system, user, and/or data communications, requests, and/or responses. Also, in place of a Web browser and information server, a combined application may be developed to perform similar operations of both. The combined application would similarly affect the obtaining and the provision of information to users, user agents, and/or the like from the RTC enabled nodes. The combined application may be nugatory on systems employing standard Web browsers.

### Mail Server

A mail server component 721 is a stored program component that is executed by a CPU 703. The mail server may be a conventional Internet mail server such as, but not limited to sendmail, Microsoft Exchange, and/or the like. The mail server may allow for the execution of program components through facilities such as ASP, ActiveX, (ANSI) (Objective-) C (++), C # and/or .NET, CGI scripts, Java, JavaScript, PERL, PHP, pipes, Python, WebObjects, and/or the like. The mail server may support communications protocols such as, but not limited to: Internet message access protocol (IMAP), Messaging Application Programming Interface (MAPI)/Microsoft Exchange, post office protocol (POP3), simple mail transfer protocol (SMTP), and/or the like. The mail server can route, forward, and process incoming and outgoing mail messages that have been sent, relayed and/or otherwise traversing through and/or to the RTC.

Access to the RTC mail may be achieved through a number of APIs offered by the individual Web server components and/or the operating system.

Also, a mail server may contain, communicate, generate, obtain, and/or provide program component, system, user, and/or data communications, requests, information, and/or responses.

### Mail Client

A mail client component 722 is a stored program component that is executed by a CPU 703. The mail client may be a conventional mail viewing application such as Apple Mail, Microsoft Entourage, Microsoft Outlook, Microsoft Outlook Express, Mozilla, Thunderbird, and/or the like. Mail clients may support a number of transfer protocols, such as: IMAP, Microsoft Exchange, POP3, SMTP, and/or the like. A mail client may communicate to and/or with other components in a component collection, including itself, and/or facilities of the like. Most frequently, the mail client communicates with mail servers, operating systems, other mail clients, and/or the like; e.g., it may contain, communicate, generate, obtain, and/or provide program component, system, user, and/or data communications, requests, information, and/or responses. Generally, the mail client provides a facility to compose and transmit electronic mail messages.

### Cryptographic Server

A cryptographic server component 720 is a stored program component that is executed by a CPU 703, cryptographic processor 726, cryptographic processor interface 727, cryptographic processor device 728, and/or the like. Cryptographic processor interfaces will allow for expedition of encryption and/or decryption requests by the cryptographic component; however, the cryptographic component, alternatively, may run on a conventional CPU. The cryptographic component allows for the encryption and/or decryption of provided data. The cryptographic component allows for both symmetric and asymmetric (e.g., Pretty Good Protection (PGP)) encryption and/or decryption. The cryptographic component may employ cryptographic techniques such as, but not limited to: digital certificates (e.g., X.509 authentication framework), digital signatures, dual signatures, enveloping, password access protection, public key management, and/or the like. The cryptographic component will facilitate numerous (encryption and/or decryption) security protocols such as, but not limited to: checksum, Data Encryption Standard (DES), Elliptical Curve Encryption (ECC), International Data Encryption Algorithm (IDEA), Message Digest 5 (MD5, which is a one way hash operation), passwords, Rivest Cipher (RC5), Rijndael, RSA (which is an Internet encryption and authentication system that uses an algorithm developed in 1977 by Ron Rivest, Adi Shamir, and Leonard Adleman), Secure Hash Algorithm (SHA), Secure Socket Layer (SSL), Secure Hypertext Transfer Protocol (HTTPS), and/or the like. Employing such encryption security protocols, the RTC may encrypt all incoming and/or outgoing communications and may serve as node within a virtual private network (VPN) with a wider communications network. The cryptographic component facilitates the process of “security authorization” whereby access to a resource is inhibited by a security protocol wherein the cryptographic component effects authorized access to the secured resource. In addition, the cryptographic component may provide unique identifiers of content, e.g., employing and MD5 hash to obtain a unique signature for an digital audio file. A cryptographic component may communicate to and/or with other components in a component collection, including itself, and/or facilities of the like. The cryptographic component supports encryption schemes allowing for the secure transmission of information across a communications network to enable the RTC component to engage in secure transactions if so desired. The cryptographic component facilitates the secure accessing of resources on the RTC and facilitates the access of secured resources on remote systems; i.e., it may act as a client and/or server of secured resources. Most frequently, the cryptographic component communicates with information servers, operating systems, other program components, and/or the like. The cryptographic component may contain, communicate, generate, obtain, and/or provide program component, system, user, and/or data communications, requests, and/or responses.

### The RTC Database

The RTC database component 719 may be embodied in a database and its stored data. The database is a stored program component, which is executed by the CPU; the stored program component portion configuring the CPU to process the stored data. The database may be a conventional, fault tolerant, relational, scalable, secure database such as Oracle or Sybase. Relational databases are an extension of a flat file. Relational databases consist of a series of related tables. The tables are interconnected via a key field. Use of the key field allows the combination of the tables by indexing against the key field; i.e., the key fields act as dimensional pivot points for combining information from various tables. Relationships generally identify links maintained between tables by matching primary keys. Primary keys represent fields that uniquely identify the rows of a table in a relational database. More precisely, they uniquely identify rows of a table on the “one” side of a one-to-many relationship.

Alternatively, the RTC database may be implemented using various standard data-structures, such as an array, hash, (linked) list, struct, structured text file (e.g., XML), table, and/or the like. Such data-structures may be stored in memory and/or in (structured) files. In another alternative, an object-oriented database may be used, such as Frontier, ObjectStore, Poet, Zope, and/or the like. Object databases can include a number of object collections that are grouped and/or linked together by common attributes; they may be related to other object collections by some common attributes. Object-oriented databases perform similarly to relational databases with the exception that objects are not just pieces of data but may have other types of capabilities encapsulated within a given object. If the RTC database is implemented as a data-structure, the use of the RTC database 719 may be integrated into another component such as the RTC component 735. Also, the database may be implemented as a mix of data structures, objects, and relational structures. Databases may be consolidated and/or distributed in countless variations through standard data processing techniques. Portions of databases, e.g., tables, may be exported and/or imported and thus decentralized and/or integrated.

In one embodiment, the database component 719 includes several tables 719a-d. A Users table 719a may include fields such as, but not limited to: user_ID, name, login, password, contact_info, query-history, settings, preferences, header, max_sequence_number, gender/male_probability, gender/female_probability, Ethnicity/white_probability, Ethnicity/black_probability, Ethnicity/Hispanic_probability, Ethnicity/Asian_probability, Ethnicity/other_probability, Age/under18_probability, Age/from18to20_probability, Age/from21to24_probability, Age/from25to29_probability, Age/from30to39_probability, Age/from40to49_probability, Age/over50_probability, Geo, Num_favs, Favs and/or the like. The user table may support and/or track multiple entity accounts on a RTC. An Index table 719b may include fields such as, but not limited to: index_ID, index_type, data_feed_ID(s), industry_ID(s), term(s), data_type(s), data_type_value(s), snippet(s), source(s), author(s), date(s), and/or the like. A Raw Data table 719c may include fields such as, but not limited to: raw_data_ID, data_feed_ID(s), index_ID(s), compacted data ID(s), raw_data_type, raw_data_content, fields, raw_data_parameters, and/or the like. A Compacted Data table 719d may include fields such as, but not limited to: compacted_data_ID, data_feed_ID(s), index_ID(s), raw_data (ID), raw_data_type, compacted_data_content, fields, compacted_data_parameters, Header, Sequence_number, Tags, Timestamp, User_ID, Comment_identifier, US_State, Number_of_terms, Terms, Plurals_bit_set, Number_of_qpids, Qpids, Number_of_consumer_qpids, Consumer_qpids, Number_of_text_characters, Text characters (number of UTF-8 encoded bytes), and/or the like. In one implementation, the data feed may be populated by a social media data feed (e.g., Facebook status updates, Twitter feed, and/or the like), by a market data feed (e.g., Bloomberg's PhatPipe, Dun & Bradstreet, Reuter's Tib, Triarch, etc.), and/or the like, such as, for example, through Microsoft's Active Template Library and Dealing Object Technology's real-time toolkit Rtt.Multi. A Queries table 719e may include fields such as, but not limited to: query_ID, query_type, query_configuration, query_content, fields, user_ID(s), raw_data_ID(s), compacted_data_ID(s), and/or the like.

In one embodiment, the RTC database may interact with other database systems. For example, employing a distributed database system, queries and data access by search RTC component may treat the combination of the RTC database, an integrated data security layer database as a single database entity.

In one embodiment, user programs may contain various user interface primitives, which may serve to update the RTC. Also, various accounts may require custom database tables depending upon the environments and the types of clients the RTC may need to serve. It should be noted that any unique fields may be designated as a key field throughout. In an alternative embodiment, these tables have been decentralized into their own databases and their respective database controllers (i.e., individual database controllers for each of the above tables). Employing standard data processing techniques, one may further distribute the databases over several computer systemizations and/or storage devices. Similarly, configurations of the decentralized database controllers may be varied by consolidating and/or distributing the various database components 719a-e. The RTC may be configured to keep track of various settings, inputs, and parameters via database controllers.

The RTC database may communicate to and/or with other components in a component collection, including itself, and/or facilities of the like. Most frequently, the RTC database communicates with the RTC component, other program components, and/or the like. The database may contain, retain, and provide information regarding other nodes and data.

### The RTCs

The RTC component 735 is a stored program component that is executed by a CPU. In one embodiment, the RTC component incorporates any and/or all combinations of the aspects of the RTC that was discussed in the previous figures. As such, the RTC affects accessing, obtaining and the provision of information, services, transactions, and/or the like across various communications networks. The features and embodiments of the RTC discussed herein increase network efficiency by reducing data transfer requirements the use of more efficient data structures and mechanisms for their transfer and storage. As a consequence, more data may be transferred in less time, and latencies with regard to transactions, are also reduced. In many cases, such reduction in storage, transfer time, bandwidth requirements, latencies, etc., will reduce the capacity and structural infrastructure requirements to support the RTC's features and facilities, and in many cases reduce the costs, energy consumption/requirements, and extend the life of RTC's underlying infrastructure; this has the added benefit of making the RTC more reliable. Similarly, many of the features and mechanisms are designed to be easier for users to use and access, thereby broadening the audience that may enjoy/employ and exploit the feature sets of the RTC; such ease of use also helps to increase the reliability of the RTC. In addition, the feature sets include heightened security as noted via the Cryptographic components 720, 726, 728 and throughout, making access to the features and data more reliable and secure

The RTC transforms raw data, query, and, UI interaction inputs via RTC Query Processing 2041, Faceted Search 2042, Record Compacting 2043, and Field Selecting 2044 components into query result outputs.

The RTC component enabling access of information between nodes may be developed by employing standard development tools and languages such as, but not limited to: Apache components, Assembly, ActiveX, binary executables, (ANSI) (Objective-) C (++), C # and/or .NET, database adapters, CGI scripts, Java, JavaScript, mapping tools, procedural and object oriented development tools, PERL, PHP, Python, shell scripts, SQL commands, web application server extensions, web development environments and libraries (e.g., Microsoft's ActiveX; Adobe AIR, FLEX & FLASH; AJAX; (D)HTML; Dojo, Java; JavaScript; jQuery(UI); MooTools; Prototype; script.aculo.us; Simple Object Access Protocol (SOAP); SWFObject; Yahoo! User Interface; and/or the like), WebObjects, and/or the like. In one embodiment, the RTC server employs a cryptographic server to encrypt and decrypt communications. The RTC component may communicate to and/or with other components in a component collection, including itself, and/or facilities of the like. Most frequently, the RTC component communicates with the RTC database, operating systems, other program components, and/or the like. The RTC may contain, communicate, generate, obtain, and/or provide program component, system, user, and/or data communications, requests, and/or responses.

### Distributed RTCs

The structure and/or operation of any of the RTC node controller components may be combined, consolidated, and/or distributed in any number of ways to facilitate development and/or deployment. Similarly, the component collection may be combined in any number of ways to facilitate deployment and/or development. To accomplish this, one may integrate the components into a common code base or in a facility that can dynamically load the components on demand in an integrated fashion.

The component collection may be consolidated and/or distributed in countless variations through standard data processing and/or development techniques. Multiple instances of any one of the program components in the program component collection may be instantiated on a single node, and/or across numerous nodes to improve performance through load-balancing and/or data-processing techniques. Furthermore, single instances may also be distributed across multiple controllers and/or storage devices; e.g., databases. All program component instances and controllers working in concert may do so through standard data processing communication techniques.

The configuration of the RTC controller will depend on the context of system deployment. Factors such as, but not limited to, the budget, capacity, location, and/or use of the underlying hardware resources may affect deployment requirements and configuration. Regardless of if the configuration results in more consolidated and/or integrated program components, results in a more distributed series of program components, and/or results in some combination between a consolidated and distributed configuration, data may be communicated, obtained, and/or provided. Instances of components consolidated into a common code base from the program component collection may communicate, obtain, and/or provide data. This may be accomplished through intra-application data processing communication techniques such as, but not limited to: data referencing (e.g., pointers), internal messaging, object instance variable communication, shared memory space, variable passing, and/or the like.

If component collection components are discrete, separate, and/or external to one another, then communicating, obtaining, and/or providing data with and/or to other component components may be accomplished through inter-application data processing communication techniques such as, but not limited to: Application Program Interfaces (API) information passage; (distributed) Component Object Model ((D)COM), (Distributed) Object Linking and Embedding ((D)OLE), and/or the like), Common Object Request Broker Architecture (CORBA), Jini local and remote application program interfaces, JavaScript Object Notation (JSON), Remote Method Invocation (RMI), SOAP, process pipes, shared files, and/or the like. Messages sent between discrete component components for inter-application communication or within memory spaces of a singular component for intra-application communication may be facilitated through the creation and parsing of a grammar. A grammar may be developed by using development tools such as lex, yacc, XML, and/or the like, which allow for grammar generation and parsing capabilities, which in turn may form the basis of communication messages within and between components.

For example, a grammar may be arranged to recognize the tokens of an HTTP post command, e.g.:
w3c-post http:// . . . Value1

where Value1 is discerned as being a parameter because “http://” is part of the grammar syntax, and what follows is considered part of the post value. Similarly, with such a grammar, a variable “Value1” may be inserted into an “http://” post command and then sent. The grammar syntax itself may be presented as structured data that is interpreted and/or otherwise used to generate the parsing mechanism (e.g., a syntax description text file as processed by lex, yacc, etc.). Also, once the parsing mechanism is generated and/or instantiated, it itself may process and/or parse structured data such as, but not limited to: character (e.g., tab) delineated text, HTML, structured text streams, XML, and/or the like structured data. In another embodiment, inter-application data processing protocols themselves may have integrated and/or readily available parsers (e.g., JSON, SOAP, and/or like parsers) that may be employed to parse (e.g., communications) data. Further, the parsing grammar may be used beyond message parsing, but may also be used to parse: databases, data collections, data stores, structured data, and/or the like. Again, the desired configuration will depend upon the context, environment, and requirements of system deployment.

For example, in some implementations, the RTC controller may be executing a PHP script implementing a Secure Sockets Layer (“SSL”) socket server via the information sherver, which listens to incoming communications on a server port to which a client may send data, e.g., data encoded in JSON format. Upon identifying an incoming communication, the PHP script may read the incoming message from the client device, parse the received JSON-encoded text data to extract information from the JSON-encoded text data into PHP script variables, and store the data (e.g., client identifying information, etc.) and/or extracted information in a relational database accessible using the Structured Query Language (“SQL”). An exemplary listing, written substantially in the form of PHP/SQL commands, to accept JSON-encoded input data from a client device via a SSL connection, parse the data to extract variables, and store the data to a database, is provided below:

```
<?PHP
header(‘Content-Type: text/plaid’);
// set ip address and port to listen to for incoming data
$address = ‘192.168.0.100’;
$port = 255;
// create a server-side SSL socket, listen for/accept incoming
communication
$sock = socket_create(AF_INET, SOCK_STREAM, 0);
socket_bind($sock, $address, $port) or die(‘Could not bind to address’);
socket_listen($sock);
$client = socket_accept($sock);
// read input data from client device in 1024 byte blocks until end of
message
do {
  $input = “”;
  $input = socket_read($client, 1024);
  $data .= $input;
} while($input != “”);
// parse data to extract variables
$obj = json_decode($data, true);
// store input data in a database
mysql_connect(“201.408.185.132”,$DBserver,$password); // access
database server
mysql_select(“CLIENT_DB.SQL”); // select database to append
mysql_query(“INSERT INTO UserTable (transmission)
VALUES ($data)”); // add data to UserTable table in a CLIENT database
mysql_close(“CLIENT_DB.SQL”); // close connection to database
?>
```

Also, the following resources may be used to provide example embodiments regarding SOAP parser implementation:

http://www.xav.com/perl/site/lib/SOAP/Parser.html

http://publib.boulder.ibm.com/infocenter/tivihelp/v2r1/index.jsp?topic=/com.ibm.IBMDI.doc/referenceguide295.htm

and other parser implementations:

http://publib.boulder.ibm.com/infocenter/tivihelp/v2r1/index.jsp?topic=/com.ibm.IBMDI.doc/referenceguide259.htm

all of which are hereby expressly incorporated by reference.

In order to address various issues and advance the art, the entirety of this application for APPARATUSES, METHODS AND SYSTEMS FOR EFFICIENT AD-HOC QUERYING OF DISTRIBUTED DATA (including the Cover Page, Title, Headings, Field, Background, Summary, Brief Description of the Drawings, Detailed Description, Claims, Abstract, Figures, Appendices, and otherwise) shows, by way of illustration, various embodiments in which the claimed innovations may be practiced. The advantages and features of the application are of a representative sample of embodiments only, and are not exhaustive and/or exclusive. They are presented only to assist in understanding and teach the claimed principles. It should be understood that they are not representative of all claimed innovations. As such, certain aspects of the disclosure have not been discussed herein. That alternate embodiments may not have been presented for a specific portion of the innovations or that further undescribed alternate embodiments may be available for a portion is not to be considered a disclaimer of those alternate embodiments. It will be appreciated that many of those undescribed embodiments incorporate the same principles of the innovations and others are equivalent. Thus, it is to be understood that other embodiments may be utilized and functional, logical, operational, organizational, structural and/or topological modifications may be made without departing from the scope and/or spirit of the disclosure. As such, all examples and/or embodiments are deemed to be non-limiting throughout this disclosure. Also, no inference should be drawn regarding those embodiments discussed herein relative to those not discussed herein other than it is as such for purposes of reducing space and repetition. For instance, it is to be understood that the logical and/or topological structure of any combination of any program components (a component collection), other components and/or any present feature sets as described in the figures and/or throughout are not limited to a fixed operating order and/or arrangement, but rather, any disclosed order is exemplary and all equivalents, regardless of order, are contemplated by the disclosure. Furthermore, it is to be understood that such features are not limited to serial execution, but rather, any number of threads, processes, services, servers, and/or the like that may execute asynchronously, concurrently, in parallel, simultaneously, synchronously, and/or the like are contemplated by the disclosure. As such, some of these features may be mutually contradictory, in that they cannot be simultaneously present in a single embodiment. Similarly, some features are applicable to one aspect of the innovations, and inapplicable to others. In addition, the disclosure includes other innovations not presently claimed. Applicant reserves all rights in those presently unclaimed innovations including the right to claim such innovations, file additional applications, continuations, continuations in part, divisions, and/or the like thereof. As such, it should be understood that advantages, embodiments, examples, functional, features, logical, operational, organizational, structural, topological, and/or other aspects of the disclosure are not to be considered limitations on the disclosure as defined by the claims or limitations on equivalents to the claims.

1.-6. (canceled)

7. A processor-implemented method, comprising:
receiving a raw data record configured as a JSON file from at least one social media feed;
selecting a plurality of data fields based on at least one data domain;
extracting field data values associated with each of the plurality of data fields from the raw data record;
providing the field data values to a record compactor to generate a bit-packed data record, including:
tokenizing at least one of the field data values to yield a plurality of terms,
hashing each of the plurality of terms to generate a plurality of hashes,
counting occurrences of each of the plurality of hashes to generate a plurality of hash occurrence counts,
generating a hash map associating each of the plurality of hash occurrence counts to each of the plurality of hashes,
comparing the each of the plurality of hash occurrence counts to a threshold count value,
appending the each of the plurality of hashes and a corresponding one of the plurality of hash occurrence counts to a dictionary file when the each of the plurality of hash occurrence counts is greater than the second threshold count value, wherein the dictionary file comprises a tab-separated value (TSV) file,
sorting the plurality of hashes in the second data file into a term array based on corresponding values of the plurality of hash occurrence counts, and
associating each of the plurality of hashes with a corresponding index value in the term array;
partitioning the bit-packed data record into a plurality of record slices; and
transmitting each of the record slices to at least one of a plurality of worker nodes in an Akka cluster, wherein each of the plurality of worker nodes builds a facet index comprising a tree map based on the record slices received by that node.

8. A processor-implemented method, comprising:
receiving a raw data record;
selecting a plurality of data fields based on at least one data domain;
extracting field data values associated with each of the plurality of data fields from the raw data record;
providing the field data values to a record compactor to generate a bit-packed data record;
partitioning the bit-packed data record into a plurality of record slices; and
transmitting each of the record slices to at least one of a plurality of worker nodes in a cluster.

9. The method of claim 8, wherein providing the field data values to a record compactor to generate a bit-packed record further comprises:
generating a bit vector of enabled/disabled flags based on at least one of the field data values.

10. The method of claim 8, wherein providing the field data values to a record compactor to generate a bit-packed record further comprises:
configuring at least one of the field data values as a SIP hash.

11. The method of claim 8, wherein providing the field data values to a record compactor to generate a bit-packed record further comprises:
configuring at least one of the field data values that takes one of N values as a byte or short datatype.

12. The method of claim 8, wherein providing the field data values to a record compactor to generate a bit-packed record further comprises:
tokenizing at least one of the field data values to yield a plurality of terms;
hashing each of the plurality of terms to generate a plurality of hashes;
counting occurrences of each of the plurality of hashes to generate a plurality of hash occurrence counts; and
generating a hash map associating each of the plurality of hash occurrence counts to each of the plurality of hashes.

13. The method of claim 12, further comprising:
comparing each of the plurality of hash occurrence counts to a first threshold count value; and
appending the each of the plurality of hashes to a first dictionary file when the each of the plurality of hash occurrence counts is greater than the first threshold count value.

14. The method of claim 13, further comprising:
comparing the each of the plurality of hash occurrence counts to a second threshold count value, wherein the second threshold count value is greater than the first threshold count value; and
appending the each of the plurality of hashes and a corresponding one of the plurality of hash occurrence counts to a second dictionary file when the each of the plurality of hash occurrence counts is greater than the second threshold count value.

15. The method of claim 14, wherein the first and second dictionary files are tab-separated value (TSV) files.

16. The method of claim 14, further comprising:
sorting the plurality of hashes in the second data file into a term array based on corresponding values of the plurality of hash occurrence counts.

17. The method of claim 16, further comprising:
associating each of the plurality of hashes with a corresponding index value in the term array.

18. The method of claim 8, wherein the raw data record is configured as a JSON file.

19. The method of claim 8, wherein the raw data record is received via at least one social media data feed.

20. The method of claim 19, wherein the raw data record corresponds to at least one social media comment.

21. The method of claim 8, wherein the raw data record is received via at least one market data feed.

22. The method of claim 8, wherein the cluster is an Akka cluster.

23. The method of claim 8, wherein each of the plurality of worker nodes builds a facet index based on the record slices received by that node.

24. The method of claim 23, wherein the facet index comprises a tree map.

25. A system, comprising:
a processor;
a memory disposed in communication with the processor and storing instructions causing the processor to:
receive a raw data record;
select a plurality of data fields based on at least one data domain;
extract field data values associated with each of the plurality of data fields from the raw data record;
provide the field data values to a record compactor to generate a bit-packed data record;
partition the bit-packed data record into a plurality of record slices; and
transmit each of the record slices to at least one of a plurality of worker nodes in a cluster.

26. A processor-accessible non-transitory medium storing processor-issuable instructions, comprising:
receive a raw data record;
select a plurality of data fields based on at least one data domain;
extract field data values associated with each of the plurality of data fields from the raw data record;
provide the field data values to a record compactor to generate a bit-packed data record;
partition the bit-packed data record into a plurality of record slices; and
transmit each of the record slices to at least one of a plurality of worker nodes in a cluster.
